(19) United States
(12) Patent Application Publication
(10) Pub. No.: US 2016/0093769 A1
(43) Pub. Date: Mar. 31, 2016

(54) LIGHT-EMITTING DIODE WITH PASSIVATION LAYER

(71) Applicant: OSRAM OPTO SEMICONDUCTORS GMBH, Regensburg (DE)

(72) Inventors: Sabine vom Dorp, Altdorf (DE); Markus Maute, Alteglofsheim (DE)

(21) Appl. No.: 14/891,972

(22) PCT Filed: Jun. 5, 2014
(86) PCT No.: PCT/EP2014/061732

§ 371 Date: Nov. 18, 2015

(30) Foreign Application Priority Data
Jun. 6, 2013 (DE) 10 2013 105 870.1

(51) Int. Cl. H01L 33/24; H01L 33/62; H01L 27/15; H01L 33/56; H01L 33/60; H01L 33/00; H01L 33/54

(52) U.S. Cl. CPC H01L 33/24; H01L 33/007; H01L 33/62; H01L 33/54; H01L 33/56; H01L 33/60; H01L 27/156; H01L 33/0079; H01L 2933/0033; H01L 2933/005; H01L 2933/0058; H01L 2933/0066; H01L 2933/0016

(57) ABSTRACT

An optoelectronic semiconductor chip includes a carrier substrate; a semiconductor body having a circumferential lateral surface, including a first and a second semiconductor region and, arranged there between, an active zone that generates radiation; and a connection structure including a first and a second conductive connection layer, separated from one another, wherein the first connection layer electrically connects to the first semiconductor region and the second connection layer via at least one plated-through hole electrically connects to the second semiconductor region, wherein the semiconductor body is surrounded by a passivation layer arranged on the lateral surface, and at least one further layer is arranged in a region surrounding the passivation layer.

### TECHNICAL FIELD

This disclosure relates to an optoelectronic semiconductor chip and a method of producing an optoelectronic semiconductor chip.

### SUMMARY

We provide a method of producing an optoelectronic semiconductor chip including forming a semiconductor layer sequence on a starting substrate including a first and a second semiconductor region and, arranged there between, an active zone that generates radiation; structuring the semiconductor layer sequence, wherein a semiconductor structure in the form of an elevation having a circumferential lateral surface is formed by material of the semiconductor layer sequence being removed in a region surrounding the semiconductor structure at least as far as a depth such that the active zone is exposed at the circumferential lateral surface; forming a passivation layer arranged on the circumferential lateral surface of the semiconductor structure; forming a connection structure in the region of the semiconductor structure after forming the passivation layer, including a first and a second conductive connection layer separated from one another, wherein the first connection layer electrically connects to the first semiconductor region, and the second connection layer via at least one plated-through hole electrically connects to the second semiconductor region; forming a mirror layer in the region of the plated-through hole and/or in a region laterally surrounding the semiconductor structure; connecting the connection structure to a carrier substrate; and removing the starting substrate.

We also provide an optoelectronic semiconductor chip, including a carrier substrate; a semiconductor body having a circumferential lateral surface, including a first and a second semiconductor region and, arranged there between, an active zone that generates radiation; and a connection structure including a first and a second conductive connection layer, separated from one another, wherein the first connection layer electrically connects to the first semiconductor region and the second connection layer via at least one plated-through hole electrically connects to the second semiconductor region, wherein the semiconductor body is surrounded by a passivation layer arranged on the lateral surface, and at least one further layer is arranged in a region surrounding the passivation layer.

We further provide a method of producing an optoelectronic semiconductor chip including forming a semiconductor layer sequence on a starting substrate, including a first and a second semiconductor region and, arranged there between, an active zone that generates radiation; structuring the semiconductor layer sequence, wherein a semiconductor structure in the form of an elevation having a circumferential lateral surface is formed by material of the semiconductor layer sequence being removed in a region surrounding the semiconductor structure at least as far as a depth such that the active zone is exposed at the circumferential lateral surface; forming a passivation layer arranged on the circumferential lateral surface of the semiconductor structure; forming a connection structure in the region of the semiconductor structure after forming the passivation layer, including first and a second conductive connection layer separated from one another, wherein the first connection layer electrically connects to the first semiconductor region and the second connection layer via at least one plated-through hole electrically connects to the second semiconductor region; connecting the connection structure to a carrier substrate; and removing the starting substrate.

The above-described properties, features and advantages and the way in which they are achieved will become clearer and more clearly understood in association with the following description of examples explained in greater detail in association with the schematic drawings.

### BRIEF DESCRIPTION OF THE DRAWINGS

FIGS. 1 to 8 show production of an optoelectronic semiconductor chip comprising a semiconductor body, a connection structure having a plurality of plated-through holes and a carrier substrate, wherein a process of structuring a semiconductor layer sequence for producing the semiconductor body and a process of passivating a lateral surface are carried out before transfer to the carrier substrate, in each case in a schematic lateral section illustration.

FIG. 9 shows a schematic plan view illustration of components of an optoelectronic semiconductor chip.

FIG. 10 shows a flow diagram of a method of producing an optoelectronic semiconductor chip.

FIG. 11 shows a schematic lateral sectional illustration of a further optoelectronic semiconductor chip comprising a front-side passivation.

FIG. 12 shows a schematic lateral sectional illustration of a further optoelectronic semiconductor chip in which semiconductor material is removed in the region of a front-side contact pad.

FIG. 13 shows a schematic lateral sectional illustration of a further optoelectronic semiconductor chip having a mirror in the region of the plated-through hole.

FIG. 14 shows a schematic lateral sectional illustration of a further optoelectronic semiconductor chip in which a protective layer is omitted in the region of a mirror.

FIG. 15 shows a schematic lateral sectional illustration of a further optoelectronic semiconductor chip in which an insulating material is arranged laterally alongside the semiconductor body, the insulating material being used for a planarization in the context of production.

FIG. 16 shows a schematic lateral sectional illustration of a further optoelectronic semiconductor chip in which, in the context of production, an additional metallic layer is formed after the process of structuring the semiconductor body and the process of passivating the lateral surface.

FIG. 17 shows a schematic lateral sectional illustration of a further optoelectronic semiconductor chip in which a connection layer of the connection structure is omitted in a region laterally with respect to the semiconductor body.

FIG. 18 shows a schematic lateral sectional illustration of a further optoelectronic semiconductor chip comprising a mirror both in the region of the plated-through hole and in a region laterally surrounding the semiconductor body.

FIGS. 19 to 23 show production of a further optoelectronic semiconductor chip, wherein a semiconductor body is produced by a two-stage structuring of a semiconductor layer sequence before and after transfer to a carrier substrate, in each case in a schematic lateral sectional illustration.

### LIST OF REFERENCE SIGNS

101-110 Semiconductor chip
120 Starting substrate
125 Carrier substrate
130 Semiconductor layer sequence
131, 132 Semiconductor region
133 Active zone
135 Incipiently etched region
139 Coupling-out structure
140 Mirror layer
145 Metallic layer
150 Passivation layer
155 Insulation layer
157 Passivation layer
159 Insulating material
161, 162 Connection layer
163 Contact layer
164 Portion
165 Contact pad
169 Mirror layer
201, 202 Auxiliary line
206, 216 Auxiliary line
230 Semiconductor structure, semiconductor body
231, 232 Semiconductor structure
233 Semiconductor structure
239 Lateral surface
237 Opening
240 Semiconductor body
242 Elevation
249 Lateral surface
250 Trench structure
255 Trench region
260 Plated-through hole
301-306 Method step
A-A Sectional line

### DETAILED DESCRIPTION

The optoelectronic semiconductor chip comprises a carrier substrate, a semiconductor body having an active zone that generates radiation, and a connection structure having at least one plated-through hole. The methods are provided in particular to produce optoelectronic semiconductor chips described here such that all of the features described for the methods are also disclosed for the optoelectronic semiconductor chips, and vice versa.

One possible production of an optoelectronic semiconductor chip comprises forming a semiconductor layer sequence on a starting substrate, comprising two semiconductor regions having different conductivity types and, arranged therebetween, an active zone that generates light radiation, and forms a connection structure in the region of the semiconductor layer sequence with a plated-through hole such that the different semiconductor regions are contactable separately from one another. This arrangement is subsequently transferred to a carrier substrate by the connection structure being connected to the carrier substrate in a bonding process.

This is followed by removing the starting substrate and structuring the semiconductor layer sequence in a wet-chemical etching process. Hereby, a semiconductor structure in the form of a mesa-shaped elevation is formed which, in the semiconductor chip, serves as a semiconductor body that emits light radiation. The semiconductor body is also referred to as mesa. To protect the semiconductor body, a passivation layer is formed over a large area on a front-side surface and a circumferential lateral surface of the semiconductor body. The passivation layer is formed from one or a plurality of dielectric materials, and with regard to low absorption of light radiation. Further processes, for example, forming a contact pad suitable for wire bonding laterally alongside the semiconductor body, are carried out to complete the semiconductor chip.

During the above-described process flow which can be employed, for example, during production of the so-called UX:3 chip (Osram product designation), contamination can occur in the region of the lateral surface of the semiconductor body, as a result of which the mode of operation of the semiconductor chip is impaired. Structuring the semiconductor layer sequence, which is carried out after transfer to the carrier substrate and removal of the starting substrate, can have the effect, on account of previous processes and thus the materials and layers present on the carrier substrate, that particles, for example, silver particles or layers are deposited at the lateral surface of the semiconductor body in the region of the p-n junction or in the junction region between the different semiconductor regions. This contamination of the mesa edge can lead to an electrical shunt in the finished semiconductor chip. Deposition can occur even when costly cleaning processes are carried out.

Our method comprises forming a semiconductor layer sequence on a starting substrate comprising a first and a second semiconductor region and, arranged therebetween, an active zone that generates radiation, and structuring the semiconductor layer sequence, wherein a semiconductor structure in the form of an elevation having a circumferential lateral surface is formed. During structuring, material of the semiconductor layer sequence is removed in a region surrounding the semiconductor structure (to be produced) at least as far as a depth such that the active zone is exposed at the circumferential lateral surface. The method furthermore comprises forming a passivation layer, wherein the passivation layer is arranged (at least) on the circumferential lateral surface of the semiconductor structure, and forming a connection structure in the region of the semiconductor structure after the process of forming the passivation layer. The connection structure comprises a first and a second conductive connection layer separated from one another. The first connection layer electrically connects to the first semiconductor region, and the second connection layer, via at least one plated-through hole, electrically connects to the second semiconductor region. The method furthermore comprises connecting the connection structure to a carrier substrate and removing the starting substrate. Removing the starting substrate can be carried out after connecting the connection structure to the carrier substrate.

In the production method, the process of structuring the semiconductor layer sequence to form the semiconductor structure and the process of forming the passivation layer, which comprises an insulating material, are carried out on the starting substrate, that is to say prior to the transfer to the carrier substrate and prior to the process of forming the connection structure. In such an early method stage, only a limited number of materials and layers are present on the starting substrate. This has the consequence of reducing possible sources of contamination of the lateral surface of the semiconductor structure. The passivation formed subsequently in the form of the passivation layer that encloses the semiconductor structure and is arranged on the circumferential lateral surface protects the lateral surface of the semiconductor structure, in particular in the junction region between the first and second semiconductor regions or in the region of the active zone, against deposition of particles or other undesired layers. In this way, occurrence of an electrical shunt can be avoided with high reliability.

The expression “lateral surface” is synonymous with the circumferential edge surface or the circumferential marginal region of the semiconductor structure produced by the structuring. The lateral surface is composed of all side walls or side flanks of the semiconductor structure.

Material of the semiconductor layer sequence may be removed as far as the starting substrate during the process of structuring the semiconductor layer sequence. As a result, the semiconductor structure produced by the structuring can already have the form of a semiconductor body of the optoelectronic semiconductor chip, the semiconductor body being used to emit light radiation, or the semiconductor structure can constitute the semiconductor body. During operation of the semiconductor chip, the light radiation can be generated in the active zone and emitted via a front side of the semiconductor body (light exit side). Since structuring the semiconductor layer sequence is carried out prior to transfer to the carrier substrate, the semiconductor body can have a shape or cross-sectional shape at least partly widening in the direction of the front side. This configuration promotes coupling-out of light from the semiconductor body.

By virtue of the fact that material of the semiconductor layer sequence is removed as far as the starting substrate during the process of structuring the semiconductor layer sequence, it is possible for the mesa structuring to be completely carried out during structuring of the semiconductor layer sequence. As a result, it is also possible, in particular, for the lateral surface of the semiconductor body to be completely covered by the passivation layer. It follows that the passivation layer can extend as far as the top side of the second semiconductor region facing away from the carrier substrate.

Structuring the semiconductor layer sequence may comprise carrying out a dry-chemical etching process. Dry-chemical etching can be appropriate in particular for the above-described structuring of the semiconductor layer sequence right down to the starting substrate. In this case, an etch stop can be effected on the starting substrate. Dry-chemical etching enables a modification of a semiconductor surface, in this present case the lateral surface of the semiconductor structure, such that a reduced electrical conductivity or no conductivity any longer can be present in this region. Formation of a shunt can be additionally suppressed as a result.

The insulating passivation layer is used in an early method stage to protect the lateral surface of the semiconductor structure. Areally covering a semiconductor body as carried out in a conventional production method is not provided here. The spatially delimited use results in a large degree of freedom in the choice of the material for the passivation layer. Instead of silicon oxide, for example, a material having a higher absorption in the wavelength range of the light radiation of the optoelectronic semiconductor chip is usable, the material having improved passivation properties. For this purpose, in accordance with a further example, provision is made for the passivation layer to comprise silicon nitride.

The first and second semiconductor regions of the semiconductor layer sequence have different conductivity types. The semiconductor layer sequence can be formed on the starting substrate, for example, such that the first semiconductor region is present on a side of the semiconductor layer sequence facing away from the starting substrate, and the second semiconductor region faces the starting substrate or is arranged on the starting substrate. It is furthermore possible, for example, for the first semiconductor region to be a p-conducting semiconductor region, and for the second semiconductor region to be an n-conducting semiconductor region. After the process of connecting the connection structure to the carrier substrate and the process of removing the starting substrate, the second semiconductor region can have an exposed side that can form the front or light exit side provided to emit light radiation.

The connection structure formed after the process of producing the passivation layer can comprise, alongside the first and second conductive connection layers, an insulation layer by which the first and second conductive connection layers are separated from one another. The first and second connection layers and the insulation layer can be arranged regionally one above another, and regionally between the carrier substrate and the first semiconductor region in the optoelectronic semiconductor chip produced.

The passivation layer can provide not just for a passivation of the lateral surface of the semiconductor structure. It is additionally possible for the passivation layer to bring about a separation between the first connection layer and the second semiconductor region of the semiconductor structure or the semiconductor body of the optoelectronic semiconductor chip.

The optoelectronic semiconductor chip can be a light-emitting diode chip, in particular. The semiconductor layer sequence can be based, for example, on a III-V semiconductor material system such as GaN, for example. The starting substrate can be a sapphire substrate, for example. The carrier substrate can be a germanium substrate, for example.

Connecting the connection structure to the carrier substrate can be carried out by a bonding process, for example. In the bonding process, the connection structure can be connected to the carrier substrate by the second connection layer. For this purpose, the second connection layer can comprise a sub-layer suitable for bonding, which sub-layer can be present in the form of a layer stack.

During the process of structuring the semiconductor layer sequence, a further semiconductor structure in the form of an elevation may be laterally formed alongside the semiconductor structure. The passivation layer is additionally formed in the region of a trench between the semiconductor structure and the further semiconductor structure. The connection structure is formed not only in the region of the semiconductor structure, but also in the region of the further semiconductor structure and the trench situated therebetween. Forming the further semiconductor structure makes it possible to minimize the presence of cutouts or cavities at that side of the connection structure provided for connection to the carrier substrate.

After the process of removing the starting substrate, a process of exposing the first connection layer in the region of the further semiconductor structure can furthermore be carried out. For this purpose, in this region, for example, an opening extending to the first connection layer can be produced, or the entire semiconductor material present in this region or the entire further semiconductor structure can be removed. The first semiconductor region of the semiconductor structure or of the semiconductor body of the optoelectronic semiconductor chip can be contacted by the exposed region of the first connection layer situated laterally with respect to the semiconductor body.

To improve contact, consideration can furthermore be given to forming on the exposed first connection layer a contact pad suitable for wire bonding and serves as a front-side contact. For this purpose, an additional conductive layer or metallization can be applied to the exposed first connection layer.

The first connection layer may be formed such that the first connection layer comprises a partial region that laterally surrounds the semiconductor structure and is arranged on the passivation layer. In this way, it is possible to minimize cavities in relation to connecting the connection structure to the carrier substrate.

It is possible for the passivation layer not just to be arranged on the circumferential lateral surface of the semiconductor structure, but to be formed, for example, such that the passivation layer additionally extends onto a side or top side of the semiconductor structure facing away from the starting substrate, and to cover a marginal region of side. It is furthermore possible for a layer or an arrangement of a plurality of layers to be arranged on the side of the semiconductor structure facing away from the starting substrate. In this case, the passivation layer can be formed in a manner extending as far as the layer or layer arrangement or at the edge right onto the layer or layer arrangement. Possible examples of such layers are described below.

Before the process of structuring the semiconductor layer sequence, a conductive mirror layer may be formed on the semiconductor layer sequence. The first connection layer produced later electrically connects to the first semiconductor region of the semiconductor structure by the mirror layer. The mirror layer affords the possibility, during operation of the optoelectronic semiconductor chip, of reflecting light radiation emitted by the active zone in the direction of the rear side of the semiconductor chip to the front or light exit side. The mirror layer can be formed with a shape coordinated with the semiconductor structure and the plated-through hole(s).

An additional conductive layer may be formed at least on the mirror layer such that the first connection layer electrically connects to the first semiconductor region by the conductive layer and the mirror layer. The additional conductive layer can be formed before the process of structuring the semiconductor layer sequence, in order, as a protective layer, to prevent impediment of the mirror layer in the context of the structuring of the semiconductor layer sequence.

The at least one plated-through hole may be formed by a perforation extending through the first connection layer, the first semiconductor region and the active zone into the second semiconductor region and insulated at the edge. A contact layer contacting the second semiconductor region and a partial region of the second connection layer, the partial region contacting the contact layer, are arranged within the perforation. A reliable electrical connection between the second connection layer and the second semiconductor region is possible as a result. The electrical insulation at the edge of the perforation can be realized by the abovementioned insulation layer by which the first and second connection layers are separated from one another.

The optoelectronic semiconductor chip or the connection structure can be formed either with an individual plated-through hole or with a plurality of plated-through holes arranged alongside one another.

The second semiconductor region of the semiconductor structure or of the semiconductor body can be contacted via the carrier substrate, the second connection layer and the plated-through hole(s). For this purpose, the carrier substrate can comprise a conductive substrate material, for example, doped germanium. The carrier substrate can furthermore be formed with a conductive layer serving as a rear-side contact at a side or rear side facing away from the connection structure. Furthermore, a process of thinning back the carrier substrate can be carried out before the process of forming the rear-side contact.

It is possible to jointly produce a plurality of optoelectronic semiconductor chips in an assemblage and singulate them at the end of the production method. Singulating can be carried out after the above-described process of forming the rear-side contact.

A mirror layer may be formed in the region of the at least one plated-through hole and/or in a region laterally surrounding the semiconductor structure. In this way, it is possible to obtain an improved reflection of light radiation generated during operation of the optoelectronic semiconductor chip in the direction of the front or light exit side.

After the process of forming the passivation layer, a region laterally surrounding the semiconductor structure may be filled with an insulating material. For this purpose, it is possible to carry out a process of applying the insulating material to the side of the starting substrate with the semiconductor structure, and subsequent planarization, for example, by grinding back or polishing. In this way, it is possible to avoid cavities in relation to connecting the connection structure to the carrier substrate.

After the process of removing the starting substrate, a process of roughening that side of the semiconductor structure or of the semiconductor body exposed by the removal may be carried out. This side, which can be formed by the second semiconductor region, constitutes the abovementioned front or light exit side. The roughening, which can be carried out in a suitable etching process, enables improved coupling-out of light radiation from the semiconductor body. This is the case particularly if a coupling-out structure having pyramidal structure elements is formed by the roughening.

After the process of removing the starting substrate, a further passivation layer may be formed, which is arranged on a front side of the optoelectronic semiconductor chip. The further passivation layer, in contrast to the passivation layer used to passivate the circumferential lateral surface, can comprise an insulating material having a low(er) radiation absorption, for example, silicon oxide. The further passivation layer which can be arranged at least on the semiconductor structure or on the semiconductor body of the optoelectronic semiconductor chip can enable additional protection at the front side of the semiconductor body. The further passivation layer can also be laterally present in a region with respect to the semiconductor body and/or in the region of the front-side contact pad, and can be opened for the purpose of exposing the contact pad at this location. The process of forming the further passivation layer can be carried out after the roughening mentioned above.

During the process of structuring the semiconductor layer sequence, material of the semiconductor layer sequence need not be removed as far as the starting substrate. Material removal is preferably carried out beyond the active zone. After the process of removing the starting substrate, further structuring of the semiconductor layer sequence is carried out to form a semiconductor body of the optoelectronic semiconductor chip, the semiconductor body comprising the previously produced semiconductor structure. The semiconductor layer sequence may be subjected to two separate structuring steps of forming the semiconductor body of the semiconductor chip. In the first structuring step, the semiconductor structure is formed, the circumferential lateral surface of which is subsequently provided with the passivation layer to prevent contamination and the occurrence of a shunt. In this case, the passivation layer can furthermore be arranged in the region of a trench surrounding the semiconductor structure. It is only in the second structuring step, carried out after the process of removing the starting substrate, that the shape of the semiconductor body of the semiconductor chip is defined. This procedure makes it possible to minimize cavities in relation to connecting the connection structure to the carrier substrate.

Our optoelectronic semiconductor chip may comprise a carrier substrate, a semiconductor body having a circumferential lateral surface, and a connection structure. The semiconductor body comprises a first and a second semiconductor region and, arranged therebetween, an active zone that generates radiation. The connection structure comprises a first and a second conductive connection layer separated from one another. The first connection layer electrically connects to the first semiconductor region, and the second connection layer, via at least one plated-through hole, electrically connects to the second semiconductor region. In the optoelectronic semiconductor chip, the semiconductor body is surrounded by a passivation layer arranged on the lateral surface. Furthermore, at least one further layer is arranged in a region surrounding the passivation layer.

By virtue of the fact that at least one further layer is arranged laterally alongside the passivation layer in the optoelectronic semiconductor chip, reliable protection of the semiconductor body in this region is possible. The optoelectronic semiconductor chip can be formed in accordance with the method described above or in accordance with one of the examples described above. Therefore, aspects and details described above in relation to the production method can be employed in the same way. This correspondingly applies with respect to advantages mentioned above such as avoiding electrical shunts in particular.

The presence of at least one further layer in a region surrounding the passivation layer can furthermore prove to be advantageous with regard to a configuration of the semiconductor chip with a contact pad arranged laterally alongside the semiconductor body. As a result, for example, for a wire bonding process carried out erroneously, the occurrence of a direct short circuit between the contact pad and the semiconductor body can be avoided.

Depending on the respective production, the semiconductor body can be surrounded by the passivation layer and the at least one further layer in different ways. If, during a process of structuring the underlying semiconductor layer sequence, semiconductor material is removed as far as the associated starting substrate, the entire lateral surface of the semiconductor body can be covered by the passivation layer and thereby completely enclosed. In this way, the entire semiconductor body can be laterally surrounded by the passivation layer and the at least one further layer.

In this configuration, the semiconductor body can furthermore have the above-described shape at least partly widening in the direction of a front side. Light radiation generated during operation of the optoelectronic semiconductor chip can be emitted via the front side.

In a two-stage process of structuring the semiconductor layer sequence, as was described above, the semiconductor body can have a stepped shape in cross section at the sides such that a stepped lateral surface is present. In this case, the passivation layer and the at least one further layer can be formed after the first and before the second structuring step. In this configuration, the semiconductor body can be laterally completely enclosed by the passivation layer and the at least one further layer only in a partial region, i.e., in the region of the semiconductor structure produced in the first structuring step.

Depending on the production respectively carried out, the at least one further layer which can laterally surround or extend circumferentially around the semiconductor body together with the passivation layer can involve different layers. The further layer can be, for example, the first connection layer, a layer composed of an insulating material, a conductive layer, a conductive mirror layer, an insulation layer, via which the first and second connection layers are separated from one another, or the second connection layer. It is also possible for a plurality of the layers mentioned above to be arranged in the region laterally surrounding the passivation layer and the semiconductor body.

The advantages of the examples explained above can be employed individually or else in any desired combination with one another—apart, for example, in cases of unambiguous dependencies or incompatible alternatives.

Possible methods of producing optoelectronic semiconductor chips are described on the basis of the following schematic figures. In the methods, a semiconductor layer sequence from which a semiconductor body of the semiconductor chips emerges is at least partly structured and passivated at a lateral surface before transfer or bonding onto a carrier substrate is carried out. During structuring, semiconductor material is removed at least as far as a depth such that an active zone of the semiconductor layer sequence is exposed at the lateral surface. This procedure makes it possible to avoid occurrence of electrical shunts in the semiconductor chips with a high reliability.

In the context of production, processes known from semiconductor technology and from fabrication of optoelectronic semiconductor chips can be carried out and customary materials can be used. Hence, they will be discussed only in part. Moreover, alongside illustrated and described processes, if appropriate, further method steps can be carried out to complete the semiconductor chips. In the same way, alongside components and structures shown and described, the semiconductor chips can comprise further components, structures and/or layers. The figures are merely of schematic nature and not true to scale. In this sense, components and structures shown in the figures may be illustrated with exaggerated size or size reduction to afford a better understanding.

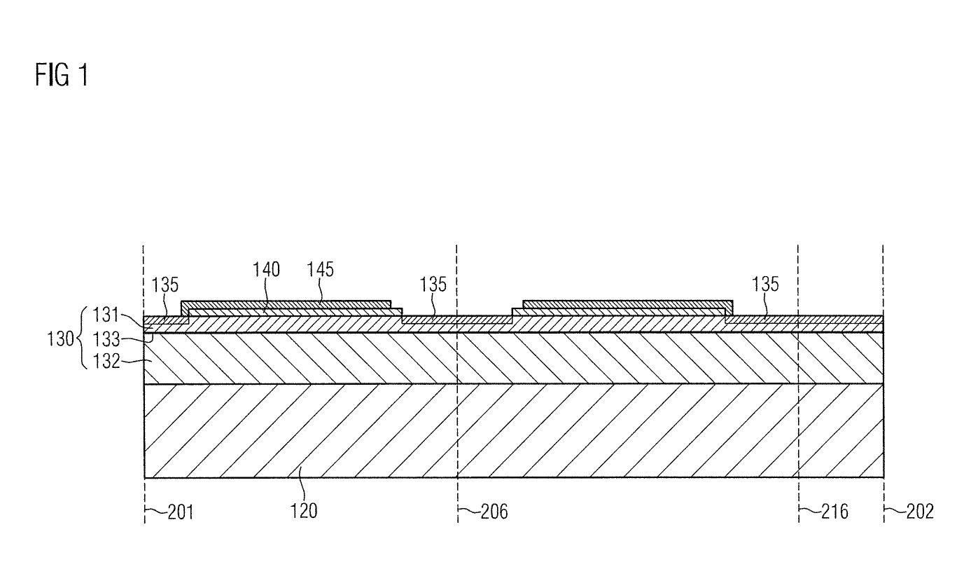

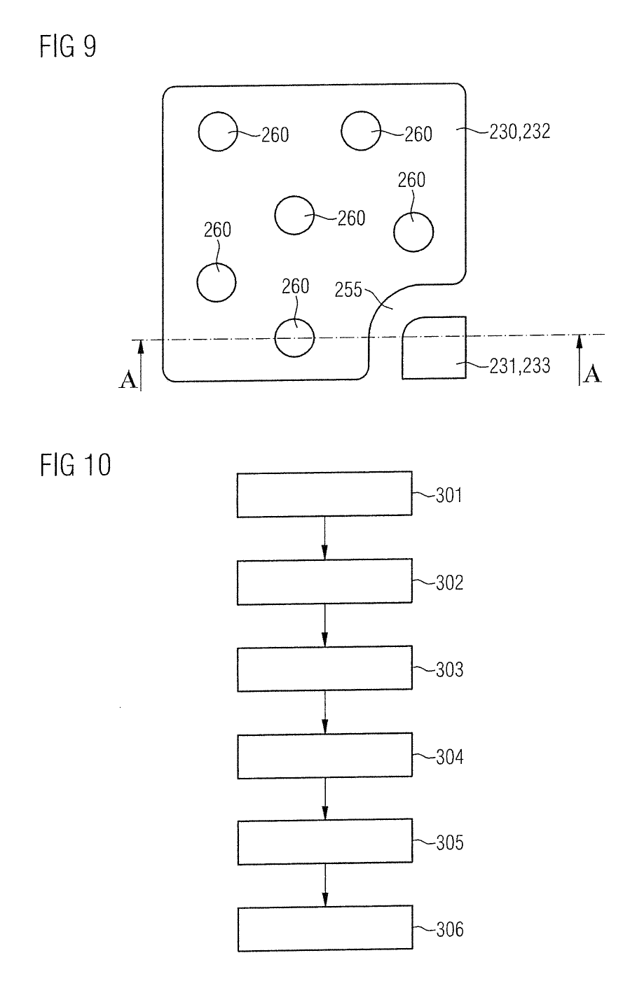

FIGS. 1 to 8 show production of a first optoelectronic semiconductor chip 101 in a schematic lateral sectional view. The semiconductor chip 101 can be, in particular, a light-emitting diode chip or LED chip. FIG. 9 shows a plan view illustration in which possible contours of structures and components of the semiconductor chip 101 are clarified. The sectional illustration in FIGS. 1 to 8 relates to the sectional plane indicated on the basis of the sectional line A-A in FIG. 9. Method steps carried out in the context of production are supplementarily summarized in the flow diagram in FIG. 10 to which reference is likewise made below.

It is pointed out that, in a parallel manner, a plurality of optoelectronic semiconductor chips 101 can be produced in the wafer assemblage and can be separated from one another by a singulation process at the end of the fabrication method. The following description, which relates principally to the production of an individual semiconductor chip 101, can apply to all of the semiconductor chips 101 processed in parallel. In this regard, the figures show as excerpts a partial region of the jointly processed assemblage. Such a partial region assigned to an individual semiconductor chip 101 is indicated with the aid of dashed auxiliary lines 201, 202 (also referred to as a grid) in the lateral sectional illustrations. A further dashed auxiliary line 206 marks the location of a plated-through hole 260 to be produced, also referred to as a via (Vertical Interconnect Access). A further auxiliary line 216 indicates the location of a front-side contact pad 165 to be produced. The contact pad 165, provided to connect a bonding wire, is formed in a region between the auxiliary lines 202, 216.

In the method, a starting arrangement shown in FIG. 1 is produced in a step 301 (cf. FIG. 10). For this purpose, first, a semiconductor layer sequence 130 is formed on a provided starting substrate 120. Forming the semiconductor layer sequence 130 is carried out with the aid of a deposition process, in particular an epitaxy process in the course of which individual semiconductor layers are successively grown on the starting substrate 120. The starting substrate 120 which comprises sapphire, for example, is also referred to as a growth or epitaxy substrate. The grown semiconductor layer sequence 130 can have a thickness in the region of 6 μm, for example.

The semiconductor layer sequence 130, which can be based on a III-V compound semiconductor material such as GaN, for example, comprises two semiconductor regions 131, 132 having different conductivity types, referred to hereinafter as first semiconductor region 131 and second semiconductor region 132, and an active zone 133 arranged between the first and second semiconductor regions 131, 132. The first semiconductor region 131 forms a side of the semiconductor layer sequence 130 facing away from the starting substrate 120. The second semiconductor region 132 is arranged on the starting substrate 120. It is possible, for example, for the first semiconductor region 131 to be p-conducting, and for the second semiconductor region 132 to be n-conducting. The active zone 133 generates light radiation upon the supply of electrical energy. The active zone 133 can comprise, for example, a p-n junction, or a quantum well structure, in particular a multi quantum well structure.

After the process of forming the semiconductor layer sequence 130, an electrically conductive or metallic mirror layer 140 is applied to the first semiconductor region 131 of the semiconductor layer sequence 130 and is structured. The mirror layer 140 can comprise, for example, a layer stack composed of an Ag layer and a ZnO layer arranged thereon.

The shape of the mirror layer 140 is coordinated with a semiconductor structure 230 formed by the structuring of the semiconductor layer sequence 130 and plated-through holes 260, which are produced later in the context of production of the optoelectronic semiconductor chip 101. FIG. 9 shows in plan view one possible configuration of the semiconductor structure 230 to be produced with a plurality of plated-through holes 260. The semiconductor structure 230 substantially has a plan view shape corresponding to a quadrilateral with a cutout in the region of one corner. A further semiconductor structure 231 is formed in the corner region. As is shown in FIG. 9, the semiconductor chip 101 can be produced with six plated-through holes 260, for example. The mirror layer 140 shown in FIG. 1 is structured such that the mirror layer 140 has in plan view an outer contour corresponding to the semiconductor structure 230 and six openings coordinated with the plated-through holes 260 to be produced, in the region of which openings the semiconductor layer sequence 130 or the first semiconductor region 131 is exposed.

After the process of forming the structured mirror layer 140, an exposed part of the first semiconductor region 131 not covered by the mirror layer 140 is incipiently etched at the surface, as is indicated on the basis of regions 135 in FIG. 1. The process of forming the incipiently etched surface regions 135 which can be carried out, for example, by a sputtering process using an Ar plasma serves for electrical deactivation. The incipiently etched regions 135 exhibit a reduced electrical conductivity compared to the rest of the semiconductor region 131 or no conductivity any longer. What can be achieved as a result is that, during operation of the optoelectronic semiconductor chip 101, a current flow to the semiconductor region 131 takes place preferably via the mirror layer 140.

In the context of step 301 (cf. FIG. 10), furthermore, a metallic layer 145 is formed on the semiconductor layer sequence 130 and the structured mirror layer 140 (or on the ZnO sub-layer thereof) and is subjected to structuring as is shown in FIG. 1. The metallic layer 145 can comprise TiW(N), for example. The metallic layer 145 serves as a protective layer of the mirror layer 140 to protect the mirror layer 140 against an etching attack during a subsequent process of structuring the semiconductor layer sequence 130. The protective metallization 145 is likewise formed with an outer contour corresponding to the semiconductor structure 230 to be produced, and with openings for the six plated-through holes 260 to be produced (cf. FIG. 9), as a result of which the mirror layer 140 is substantially completely covered by the layer 145. For the protection function, the layer 145 is furthermore formed such that the layer 145 extends around the mirror layer 140 at the outer edge as is shown in FIG. 1 and, therefore, extends in this region as far as the semiconductor layer sequence 130 or an incipiently etched surface region 135 of the first semiconductor region 131. At an inner edge of the mirror layer 140 in the region of the plated-through holes 260 to be produced, by contrast, a small part of the mirror layer 140 can be exposed.

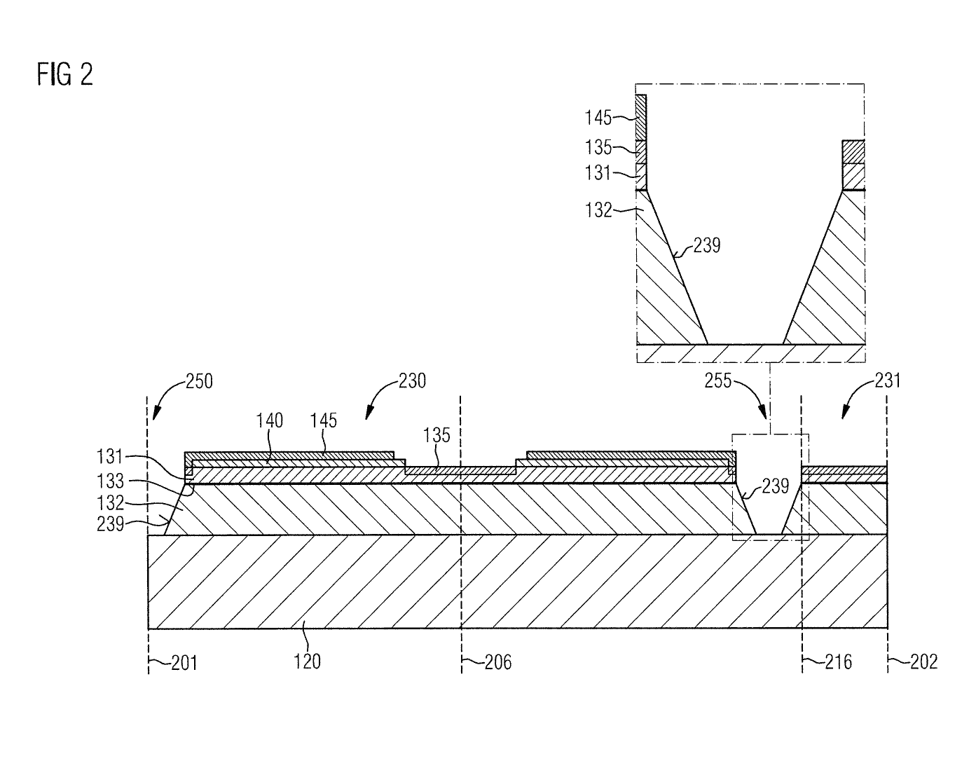

In a subsequent step 302 (cf. FIG. 10), a process of structuring the semiconductor layer sequence 130 is carried out. In this way, the abovementioned semiconductor structures 230, 231 are formed which are present in the form of elevations as shown in FIG. 2. The process of structuring the semiconductor layer sequence 130 is carried out with the aid of an etching process in which material of the semiconductor layer sequence 130 is removed in an etching region surrounding the semiconductor structures 230, 231 to be produced. After structuring, the semiconductor structure 230 or its first semiconductor region 131 in the region of the side on which the arrangement comprising the two layers 140, 145 is present has the same lateral external dimensions as the layers 140, 145 or as the metallic layer 145 extending around the mirror layer 140.

The etching process is carried out such that semiconductor material as shown in FIG. 2 is removed as far as the starting substrate 120. In this way, the semiconductor structure 230 can have the form of a semiconductor body of the optoelectronic semiconductor chip 101, the semiconductor body being used to emit light radiation, or the semiconductor structure 230 can constitute the semiconductor body of the semiconductor chip 101. The process of structuring the semiconductor layer sequence 130 is preferably carried out with the aid of a dry-chemical etching process. Reactive ion etching is suitable, for example. An etch stop can be effected on the starting substrate 120 in this case.

The semiconductor structure 230 present as a mesa-shaped elevation can also be referred to as a mesa. The semiconductor structure 230 has a circumferential lateral surface 239 at which the semiconductor regions 131, 132 and the active zone 133 present therebetween are exposed. The circumferential lateral surface 239 comprises all mutually adjoining side faces or side flanks of the semiconductor structure 230.

As shown in FIG. 2, the side faces of the semiconductor structure 230 at least in the region of the second semiconductor region 132 can run at an oblique angle with respect to a plane predefined by the starting substrate 120. As a result, the semiconductor structure 230, proceeding from the side on which the layers 140, 145 are arranged, has a shape or cross-sectional shape at least partly widening in the direction of the starting substrate 120. Apart from the illustration in FIG. 2 and the following figures, it is possible for the side faces to run obliquely with respect to the starting substrate 120 over the entire height of the semiconductor structure 230, that is to say also in the region of the first semiconductor region 131 and the active zone 133.

The further semiconductor structure 231 also has a shape at least partly widening in the direction of the starting substrate 120. This is clarified in FIG. 2 with the aid of the (partly) oblique side flank of the semiconductor structure 231 at the auxiliary line 216. An opposite side flank (not shown) of the semiconductor structure 231 (to the right of the auxiliary line 202) can have a comparable shape. The further semiconductor structure 231 is formed for the purpose that cutouts or cavities in relation to a bonding process carried out later are kept as small as possible.

In plan view, the two semiconductor structures 230, 231 can have the shape shown in FIG. 9. The semiconductor structure 230 substantially has a plan view shape corresponding to a rectangle or a square with a curved cutout in the region of one corner. The further semiconductor structure 231 arranged in the corner region and in the region of which a contact pad 165 of the optoelectronic semiconductor chip 101 is formed has a substantially quadrilateral plan view shape with a curved contour opposite the semiconductor structure 230.

FIG. 9 illustrates a configuration according to which the plated-through hole 260 in the region of the sectional line A-A is formed nearer to the side flank of the semiconductor structure 230 opposite the semiconductor structure 231 than to the opposite side flank of the semiconductor structure 230 with respect thereto. By comparison therewith, for reasons of simplification, the sectional views in FIGS. 1 to 8 illustrate a symmetrical configuration relative to the plated-through hole 260 to be produced, centrally between the side flanks of the semiconductor structure 230.

With regard to the joint production of a plurality of semiconductor chips 101, a plurality of groups comprising the two elevated semiconductor structures 230, 231 are formed, the groups being arranged alongside one another on the starting substrate 120. Partial regions or partial trenches of a continuous trench structure 250 surrounding individual semiconductor structures 230, 231 in a frame-shaped fashion are present between the semiconductor structures 230, 231. The starting substrate 120 as shown in FIG. 2 is exposed in the region of the trench structure 250.

Hereinafter, that part of the trench structure 250 present between the two semiconductor structures 230, 231 shown in FIG. 2 and the following figures is referred to as trench region 255. The trench region 255 is additionally illustrated in an enlarged view in FIG. 2. The trench region 255, as is illustrated in FIG. 9, can have a curved plan view shape.

In the production method described here, the process of structuring the semiconductor layer sequence 130 is carried out in a relatively early method stage compared to a conventional production method. The semiconductor layer sequence 130 is (still) situated on the starting substrate 120. In this method stage, furthermore, only a limited number of materials and layers are present on the starting substrate 120. Therefore, it is possible to avoid deposition of particles or layers at the lateral surface 239 of the semiconductor structure 230 produced by the structuring, in particular in the junction region between the first and second semiconductor regions 131, 132 or in the region of the active zone 133 with the risk of a shunt.

The preferred dry-chemical structuring also proves to be advantageous in this context. The dry-chemical etching can lead to a modification of the semiconductor surface such that a reduced electrical conductivity or no conductivity any longer can be present in this region. Formation of an electrical shunt despite deposition that possibly occurs can additionally be suppressed in this way.

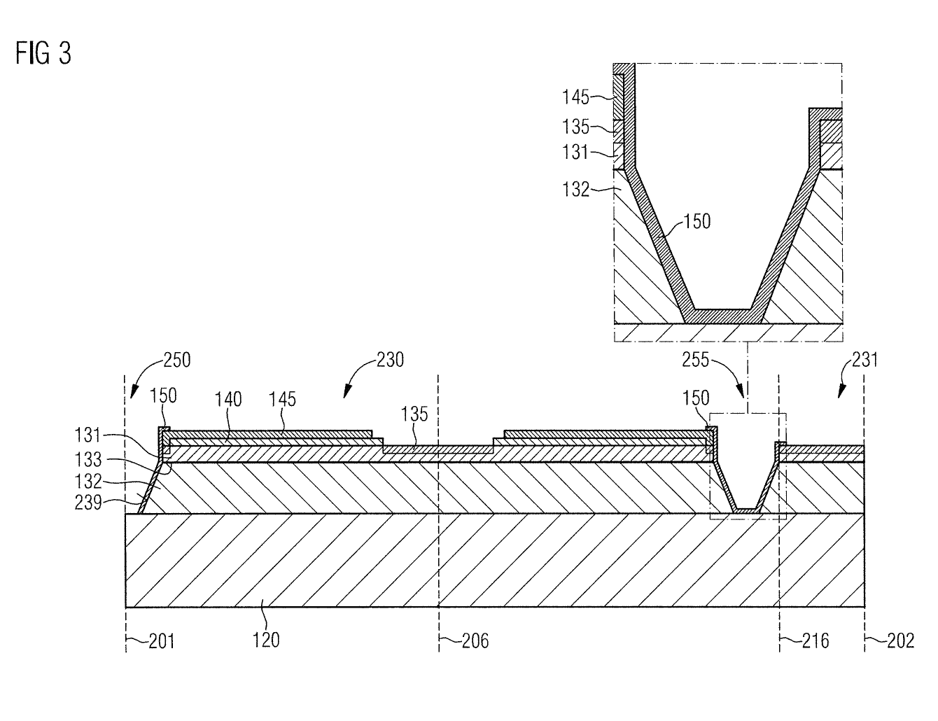

To cover or protect the circumferential lateral surface 239 of the semiconductor structure 230 for subsequent processes, the lateral surface 239 is provided with a passivation directly after the structuring step. For this purpose, in a further step 303 (cf. FIG. 10), an insulating passivation layer 150 is deposited on the substrate side with the semiconductor structures 230, 231 and is subsequently structured, as is illustrated in FIG. 3.

The passivation layer 150 formed in this way is arranged on the entire circumferential lateral surface 239 of the semiconductor structure 230 such that the semiconductor regions 131, 132 previously exposed in this region and the active zone 133 are covered. As a result, the lateral surface 239 can be protected against contamination in a subsequent process and the formation of a shunt can consequently be prevented.

As is shown in FIG. 3, the passivation layer 150 laterally completely enclosing the semiconductor structure 230 can furthermore be formed such that the passivation layer 150, proceeding from the starting substrate 120, extends right onto the side or top side of the semiconductor structure 230 directed upward in FIG. 3 and facing away from the starting substrate 120, and in this region right onto the arrangement comprising the two layers 140, 145. In this case, the passivation layer 150 covers a circumferential marginal partial region of the metallic layer 145, such that the passivation layer 150 extends around the metallic layer 145 at the outer edge.

The passivation layer 150 is furthermore formed in a manner extending to the further semiconductor structure 231 in the region of the trench region 255 as well, as is shown on the right-hand side in FIG. 3. The passivation layer 150 extends, proceeding from the lateral surface 239 of the semiconductor structure 230, over the starting substrate 120 onto the further semiconductor structure 231. In this case, the passivation layer 150 is arranged on the side face(s) of the semiconductor structure 231 opposite the semiconductor structure 230. Furthermore, the passivation layer 150 additionally covers a marginal partial region of the side or top side of the semiconductor structure 231 facing away from the starting substrate 120, such that the passivation layer 150 extends around the semiconductor structure 231 at the outer edge.

In the method, the passivation layer 150 is used in a spatially narrowly delimited region at the semiconductor structure 230, i.e., substantially at the mesa flank 239. This affords the possibility of forming the passivation layer 150 from a material from a multiplicity of possible materials. In particular, it is possible to use instead of silicon oxide conventionally used, for example, a material having a higher absorption in the wavelength range of the light radiation of the semiconductor chip 101, the material having better passivation properties. One suitable material in this regard is Si₃N₄, for example. A reduction of the luminous efficiency possibly associated with the use of such a material due to the narrow spatial delimitation on the semiconductor chip 101, is only minimal and hence negligible.

FIG. 3 additionally illustrates an enlarged view of the trench region 255 for the sake of better clarification. The trench structure 250 and thus the trench region 255 can have a height in the region of 6 μm, for example, which corresponds to the layer thickness of the previously produced semiconductor layer sequence 130. The passivation layer 150 can have a layer thickness which can be 100 nm to 1 μm, for example.

In a further step 304 (cf. FIG. 10), a connection structure is formed on the substrate side with the semiconductor structures 230, 231, the connection structure comprising two connection layers 161, 162 separated from one another and the plated-through holes 260 indicated in FIG. 9. In the optoelectronic semiconductor chip 101, the connection structure electrically contacts the different semiconductor regions 131, 132 of the semiconductor structure 230 separately from one another, and in this way making it possible to bring about an electric current flow through the active zone 133 for generating light radiation.

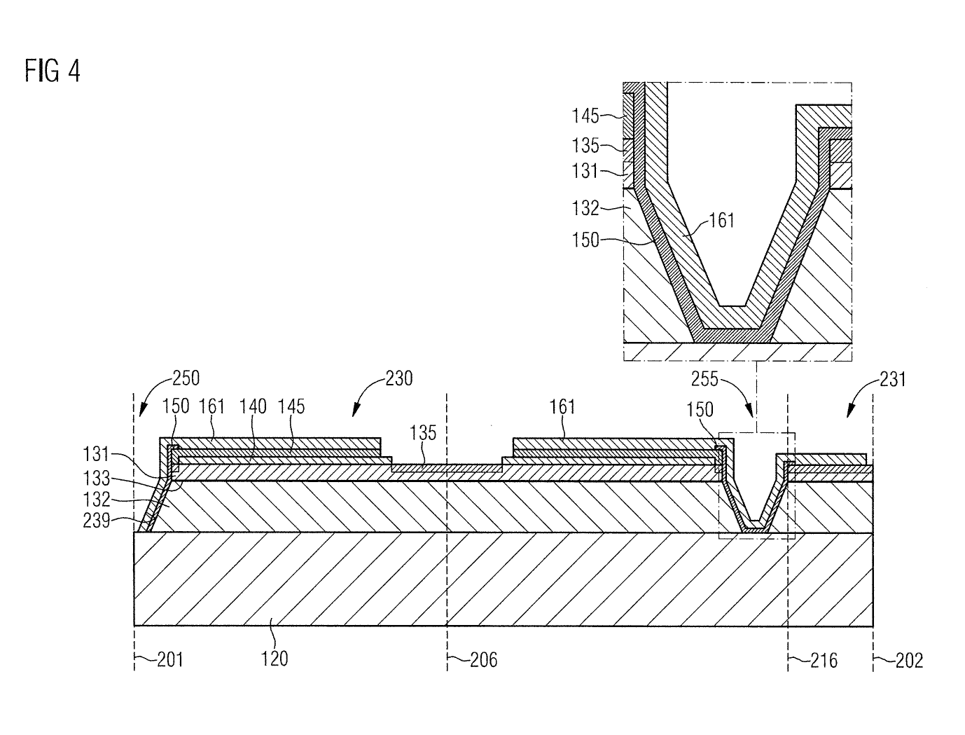

For this purpose, first, as shown in FIG. 4, a first electrically conductive or metallic connection layer 161 is applied on the substrate side with the semiconductor structures 230, 231 and is subjected to structuring. The first connection layer 161, which contacts the first semiconductor region 131 of the semiconductor structure 230, is electrically connected to the first semiconductor region 131 by the layer arrangement comprising metallic layer 145 and mirror layer 140. In the p-conducting configuration of the semiconductor region 131, the connection layer 161 can also be referred to as p-contact metal. The connection layer 161 can comprise a layer stack composed of a Pt layer, an Au layer and a Ti layer, for example.

The structured first connection layer 161 is arranged substantially on the entire semiconductor structure 230 or on the layers arranged on the semiconductor structure 230, i.e., the passivation layer 150 and the metallic layer 145. A partial region of the connection layer 161 arranged on the metallic layer 145 is formed comparably with the metallic layer 145 with openings for the six plated-through holes 260 to be produced (cf. FIG. 9).

The first connection layer 161 furthermore has a partial region in the region of the trench structure 250 arranged on the passivation layer 150 and laterally completely extends circumferentially around the semiconductor structure 230 or the lateral surface 239 thereof like the passivation layer 150. Apart from the trench region 255 between the two semiconductor structures 230, 231, the connection layer 161 in this region, as is clarified on the left-hand side in FIG. 4, can adjoin the starting substrate 120. This configuration of the connection layer 161 likewise serves for minimizing cavities in relation to a bonding process carried out later.

Furthermore, as shown on the right-hand side and in the enlarged view of the trench region 255 in FIG. 4, the first connection layer 161 has a partial region extending through the trench region 255 right onto the top side of the further semiconductor structure 231. This enables an electrical connection from a contact pad 165 produced in this region to the first semiconductor region 131 of the semiconductor structure 230. In the trench region 255, the connection layer 161 is arranged on the passivation layer 150 present here. Both in the region of the trench region 255 and in the region of the rest of the trench structure 250, the passivation layer 150 provides for an electrical insulation between the first connection layer 161 and the second semiconductor region 132 of the semiconductor structure 230. The first connection layer 161 can have a layer thickness which can be 500 nm to 2 μm, for example.

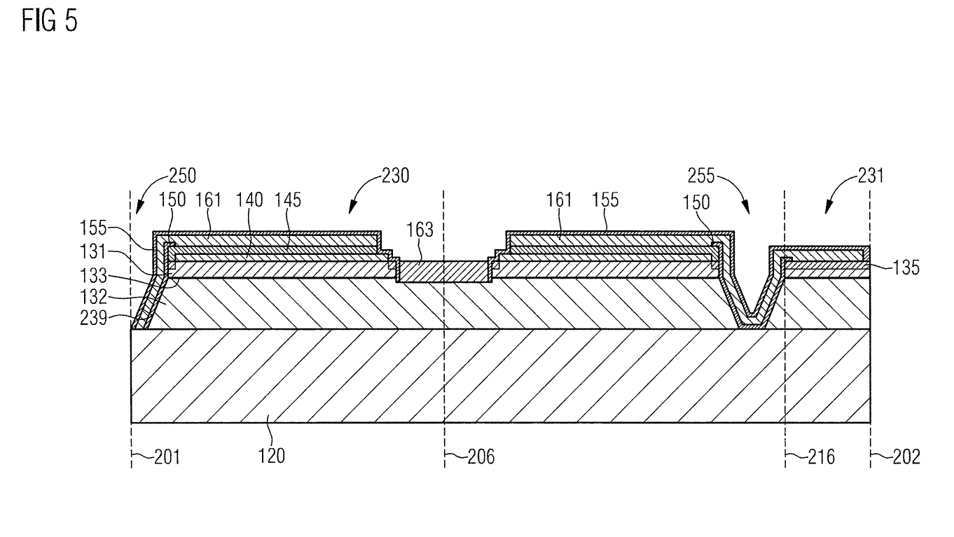

FIG. 5 shows the starting substrate 120 after carrying out further processes carried out in the context of step 304 (cf. FIG. 10) to produce the connection structure. These include forming cutouts in the semiconductor structure 230 in the region of the plated-through holes 260 to be produced, which extend through the first semiconductor region 131 and the active zone 133 such that the second semiconductor region 132 is (initially) exposed at these locations (cf. the region at the auxiliary line 206).

As furthermore becomes clear with reference to FIG. 5, an insulation layer 155 is deposited on the substrate side with the semiconductor structures 230, 231 or on the layers 161, 145, 140 and semiconductor regions 131, 132 present at this side in this stage. The insulation layer 155 can be formed from one or else from a plurality of insulating or dielectric materials such as silicon oxide and/or silicon nitride, for example. The insulation layer 155 is furthermore structured to once again expose the second semiconductor region 132 in the region of the plated-through holes 260 to be produced.

At these locations, furthermore, a portion of an electrically conductive or metallic contact layer 163 is formed by deposition and structuring. The portions of the contact layer 163 which adjoin the second semiconductor region 132 are enclosed by the insulation layer 155 at the edge, and are thereby separated from the first semiconductor region 131 and the active zone 133 (cf. the region at the auxiliary line 206). In the n-conducting configuration of the semiconductor region 132, the portions of the contact layer 163 can also be referred to as n-contacts. The contact layer 163 can comprise silver, for example.

It furthermore becomes clear with reference to FIG. 5 that, apart from the locations at which the contact layer 163 is present, the substrate side with the semiconductor structures 230, 231 is completely covered by the insulation layer 155. The insulation layer 155 therefore has a partial region in the region of the trench structure 250 which laterally completely extends circumferentially around the semiconductor structure 230. Furthermore, the insulation layer covers the entire first connection layer 161. In this way, the insulation layer 155 can ensure that the first connection layer 161 is separated from a second connection layer 162 formed subsequently. The second connection layer 162 contacts the second semiconductor region 132 of the semiconductor structure 230.

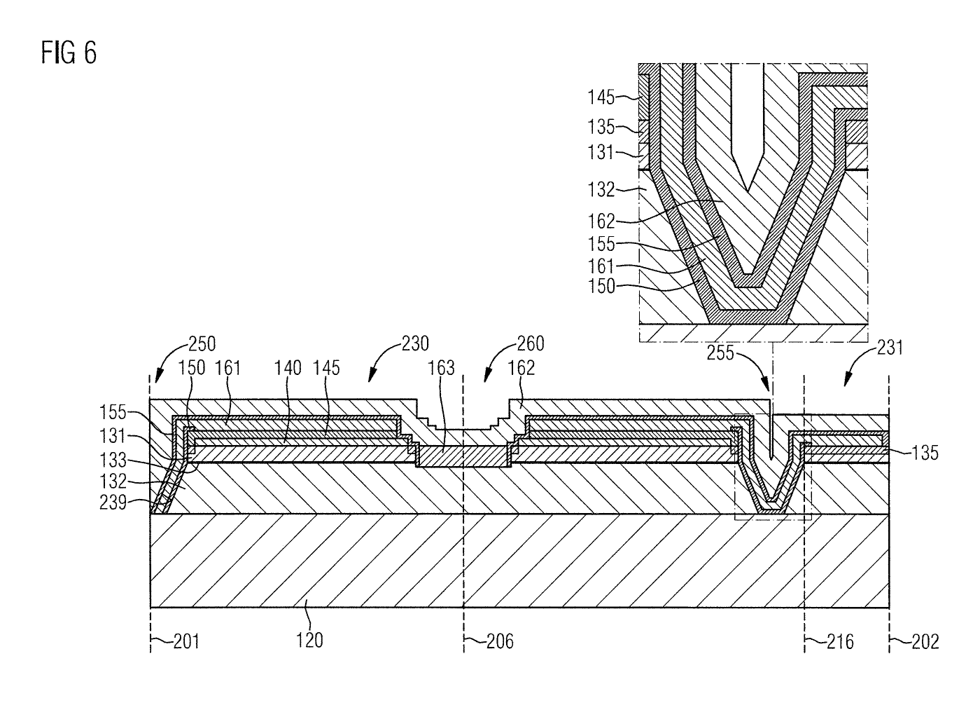

As is shown in FIG. 6, the second electrically conductive or metallic connection layer 162 is applied on the substrate side with the semiconductor structures 230, 231 or on the layers 155, 163 present at this side in this stage. The second connection layer 162 is not subjected to a further structuring and this substrate side is completely covered by the connection layer 162. As a result, the second connection layer 162 also has a partial region in the region of the trench structure 250 which laterally completely extends circumferentially around the semiconductor structure 230. With reference to FIG. 6 and the enlarged illustration of the trench region 255 shown here, it becomes clear that the trench region 255 may possibly not be completely filled after the process of forming the connection layer 162 such that a cutout can be present in this region. This can also apply to the rest of the trench structure 250. A cutout can be present (in each case) in the region of the contact layer 163 as well.

The plated-through holes 260 of the optoelectronic semiconductor chip 101 are formed by the process of applying the second connection layer 162. Each plated-through hole 260 is formed by a perforation extending through the layers 161, 145, 140, the first semiconductor region 131 and the active zone 133 into the second semiconductor region 132. The perforation is composed of the openings or cutouts previously formed at the relevant layers at this location. The insulation layer 155 used for insulation is arranged at the edge of the perforation. The contact layer 163 contacting the second semiconductor region 132 and a partial region of the connection layer 162 that contacts the contact layer 163 are arranged within the perforation.

The second connection layer 162 electrically connects to the second semiconductor region 132 of the semiconductor structure 230 via the plated-through holes 260. In this case, the insulation layer 155 ensures that the second connection layer 162 is separated from the first connection layer 161. In the region of the plated-through holes 260, the insulation layer 155 ensures that the second connection layer 162 and the contact layer 163 are separated from the first semiconductor region 131 and the active zone 133.

The second connection layer 162, which is subsequently used to produce a connection to a carrier substrate 125 can be formed, for example, in the form of a stack comprising a plurality of layers. In one possible configuration, the second connection layer 162 can comprise a barrier layer, for example, comprising a layer stack composed of Ti and/or TiW(N) and a layer composed of a bond metal arranged on the barrier layer, for example, comprising a layer stack composed of a Ti layer, a Pt layer and an Au layer.

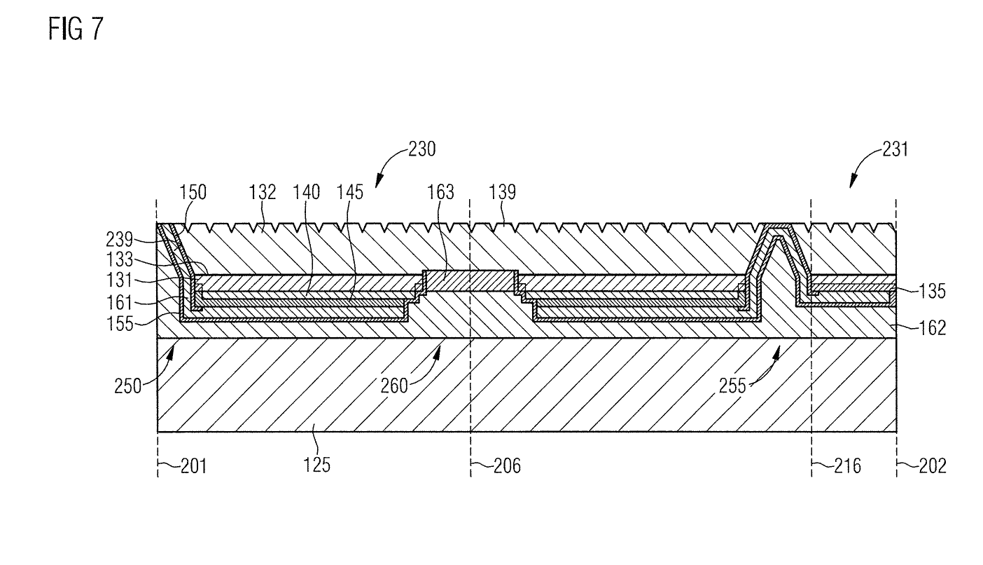

After the process of forming the connection structure comprising the layers 155, 161, 162, 163, the layer arrangement produced on the starting substrate 120 or the connection structure connects to a carrier substrate 125 in a further step 305 (cf. FIG. 10) and is thereby transferred to the carrier substrate 125 as shown in FIG. 7. FIG. 7 comprises a view rotated by 180 degrees or turned upside down relative to FIG. 6. The carrier substrate 125 comprises an electrically conductive material such as doped germanium, for example.

To produce the connection to the carrier substrate 125, a bonding process is carried out in which the second connection layer 162 or the bond metal thereof is melted. The barrier layer of the second connection layer 162 can prevent diffusion of the bond metal to the contact layer 163. For the bonding process, the carrier substrate 125 can likewise comprise a layer of a suitable bond metal at the side provided for bonding. In the bonding process, the bond layers can be melted and thereby form a common connecting layer. These layers are combined in the second connection layer 162, as shown in FIG. 7. Cutouts or cavities previously present in the region of the connection layer 162 can be filled during bonding.

The bonding process is promoted by provision of the further semiconductor structure 231 and the partial region of the first connection layer 161 present in the region of the trench structure 250 and laterally extends circumferentially around the lateral surface 239 of the semiconductor structure 230. In this way, it is possible that cutouts or cavities at that side of the second connection layer 162 provided for bonding are kept small. A reliable connection to the carrier substrate 125 can be produced as a result.

Afterward, further processes to complete the optoelectronic semiconductor chip 101 are carried out, which are combined in a further step 306 in the flow diagram in FIG. 10. They include removing the starting substrate 120 which can be implemented by carrying out a laser lift-off process, for example. As a result of the starting substrate 120 being detached, the second semiconductor region 132 of the semiconductor structure 230 is exposed at one side. This side constitutes the front side of the semiconductor chip 101, via which the semiconductor structure 230 serving as semiconductor body or mesa can emit light radiation (light exit side).

To improve the front-side light emission, the front side is furthermore roughened such that a coupling-out structure 139 is formed as shown in FIG. 7. The coupling-out structure 139 has elevations, for example, pyramidal elevations. Roughening of the front-side surface can be carried out, for example, in a wet-chemical etching method, for example, using KOH. In this case, not only the semiconductor structure 230, but also the further semiconductor structure 231 can be roughened.

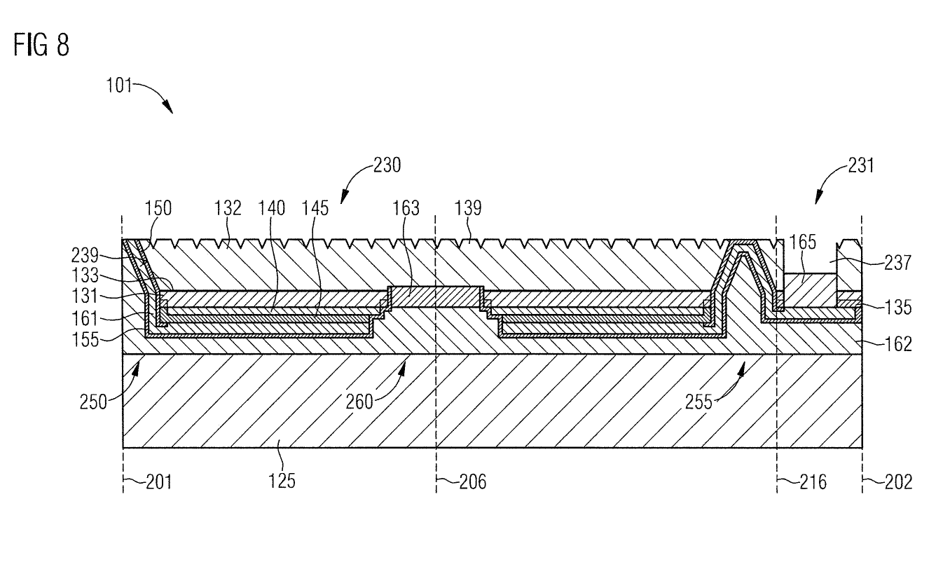

After roughening, furthermore, as shown in FIG. 8, an opening 237 is formed in the semiconductor structure 231 to expose a part of the first connection layer 161. A wet-chemical etching process, for example, can be carried out for this purpose. In this region, furthermore, a contact pad 165 (bonding pad or p-bonding pad) suitable for wire bonding and serving as a front-side contact is formed on the connection layer 161. This can be carried out by depositing a metallic layer followed by a structuring thereof.

Afterward, further processes can be carried out in step 306 (cf. FIG. 10). These include, for example, thinning back the carrier substrate 125 at a rear side facing away from the connection layer 162, and subsequently forming an electrically conductive or metallic layer serving as a rear-side contact at the rear side of the carrier substrate 125 (not illustrated). Afterward, a singulation process can be carried out to produce optoelectronic semiconductor chips 101 separated from one another. This can be carried out by dividing or dicing in the region of the auxiliary lines 201, 202.

In the optoelectronic semiconductor chip 101 produced in this way, the first and second connection layers 161, 162 and the insulation layer 155 are arranged regionally one above another, and therefore regionally between the carrier substrate 125 and the first semiconductor region 131 of the semiconductor structure 230. The semiconductor structure 230 constitutes the semiconductor body 230 used to emit light radiation during operation of the semiconductor chip 101. The first semiconductor region 131 of the semiconductor body 230 electrically connects to the contact pad 165, arranged laterally alongside the semiconductor body 230, by the mirror layer 140, the metallic layer 145 and the first connection layer 161. The second semiconductor region 132 of the semiconductor body 230 electrically connects to the rear-side contact (not shown), arranged on the carrier substrate 125, via the plated-through holes 260, the second connection layer 162 and the carrier substrate 125. During the operation of the semiconductor chip 101, an electric current flow through the semiconductor body 230 and thus through the active zone 133 thereof can be brought about via the front-side contact pad 165 and the rear-side contact, as a result of which the active zone 133 emits light radiation. The light radiation can be emitted via the front side of the semiconductor body 230 with the coupling-out structure 139. A radiation proportion emitted by the active zone 133 in the direction of the carrier substrate 125 rather than in the direction of the front side can be reflected to the front side at the mirror layer 140.

Alongside the advantages mentioned above, in particular avoiding contamination of the lateral surface 239 and thus preventing electrical shunts, the optoelectronic semiconductor chip 101 produced in accordance with the method has further advantages. The semiconductor body 230 of the semiconductor chip 101 surrounded by the passivation layer 150 arranged on the circumferential lateral surface 239 has further layers in a region laterally surrounding the passivation layer 150 (region of the trench structure 250 and of the trench region 255). In the semiconductor chip 101, the further layers are the two connection layers 161, 162 and the insulation layer 155 separating the layers 161, 162. This configuration enclosing the semiconductor body is present over the entire height or vertical extent of the semiconductor body 230. Reliable protection of the semiconductor body 230 in the region of the lateral surface 239 thereof is made possible in this way.

This holds true in particular with regard to the contact pad 165 arranged laterally alongside the semiconductor body 230, the contact pad being separated from the semiconductor body 230 not only by the layers 150, 155, 161, 162 present in the region of the trench region 255, but additionally by a remaining part of the semiconductor structure 231. In this way, it is possible to prevent the contact pad 165, which contacts the first semiconductor region 131 of the semiconductor body 230, from being short-circuited directly with the second semiconductor region 132, for example, due to a wire bonding process carried out defectively.

Furthermore, the semiconductor body 230, on account of the structuring of the underlying semiconductor layer sequence 130 prior to transfer to the carrier substrate 125, has a shape widening (at least regionally) in the direction of the front side. The configuration of the semiconductor body 230 with the side flanks opened in the emission direction promotes the coupling-out of light from the semiconductor body 230. Consequently, an increase in brightness compared with a conventional semiconductor chip is possible.

With reference to the following figures, a description is given of further examples of optoelectronic semiconductor chips or light-emitting diode chips which are modifications or developments of the semiconductor chip 101. Production can be carried out comparably with the above-described production of the semiconductor chip 101. Therefore, identical and identically acting components and structures and corresponding method steps will not be described in detail again below. Instead, with regard to already described details concerning, for example, usable materials, implementable fabrication processes, possible advantages and the like, reference is made to the explanations above. Furthermore, aspects and details mentioned in relation to one of the following examples can also apply to other examples. In particular, it is possible to combine configurations of different examples with one another.

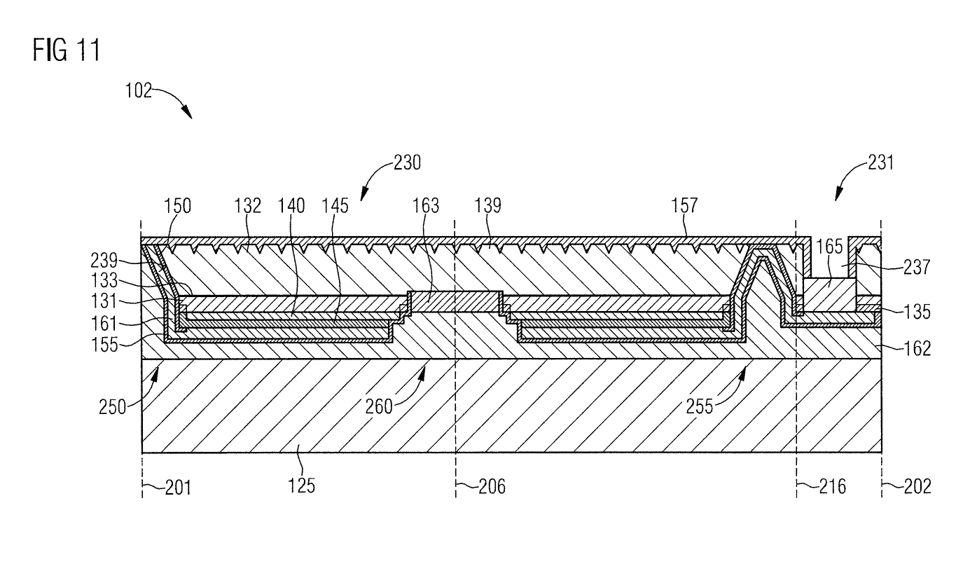

FIG. 11 shows a further optoelectronic semiconductor chip 102, which, in contrast to the semiconductor chip 101, comprises an additional insulating passivation layer 157 in the region of its front side. The passivation layer 157 is arranged in particular on the second semiconductor region 132 of the semiconductor body 230, as a result of which the semiconductor body 230 is protected at the front side. The passivation layer 157 is also arranged in a region laterally with respect to the semiconductor body 230 or in the region of the contact pad 165 and has an opening via which the contact pad 165 is accessible.

In contrast to the passivation layer 150 used at the lateral surface 239, the passivation layer 157 used for surface passivation can comprise a material having a low(er) radiation absorption, for example, silicon oxide. The passivation layer 157 can be formed in the context of step 306 (cf. FIG. 10) after the removal of the starting substrate 120 or after the production of the coupling-out structure 139 by deposition and structuring.

FIG. 11 illustrates a variant in which the passivation layer 157 is formed only after the process of opening the semiconductor structure 231 and producing the contact pad 165. As a result, the passivation layer 157 as shown in FIG. 11 can have a partial region extending to the contact pad 165 in the opening 237. Alternatively, it is possible to deposit the passivation layer 157 prior to the process of opening the semiconductor structure 231 and to structure it prior to the process of opening the semiconductor structure 231 (or together with the latter) and, subsequently, to form the contact pad 165. In this way, the passivation layer 157 can be arranged only on the front side and not extend to the contact pad 165 in the opening 237.

The process of forming a surface passivation or final passivation in the form of the front-side passivation layer 157 can also be provided in the following examples.

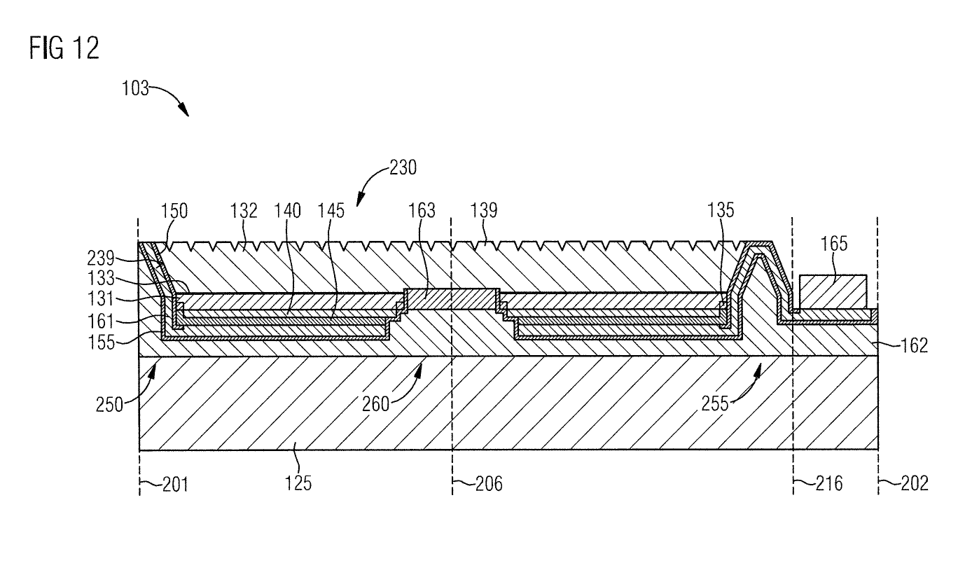

FIG. 12 shows a further optoelectronic semiconductor chip 103 in which in contrast to the semiconductor chip 101, semiconductor material in the region of the contact pad 165 or the semiconductor structure 231 previously present in this region is completely removed. For this purpose, comparably with the process of forming the opening 237, in step 306 (cf. FIG. 10), after producing the coupling-out structure 139, it is possible to carry out a wet-chemical etching process, for example. Afterward, the contact pad 165 can be formed on the exposed part of the connection layer 161. Completely removing semiconductor material in the region of the contact pad 165 affords the possibility of avoiding a short circuit between the contact pad 165 and the carrier substrate 125, brought about by semiconductor material possibly being deposited during the singulation process subsequently carried out.

In the semiconductor chip 103 in FIG. 12 or a comparable semiconductor chip without semiconductor material in the region of the contact pad 165, the surface passivation described with reference to FIG. 11 can be realized, for example, by carrying out, prior to the removal of the semiconductor material (or the semiconductor structure 231), front-side deposition and partial removal of the passivation layer 157 in the region of the contact pad 165 to be produced. It is also possible to remove the applied passivation layer 157 together with the semiconductor material. The contact pad 165 can subsequently be formed. Alternatively, the passivation layer 157 can be applied to the front side after the process of removing the semiconductor material and the process of forming the contact pad 165 and can be removed or opened in the region of the contact pad 165.

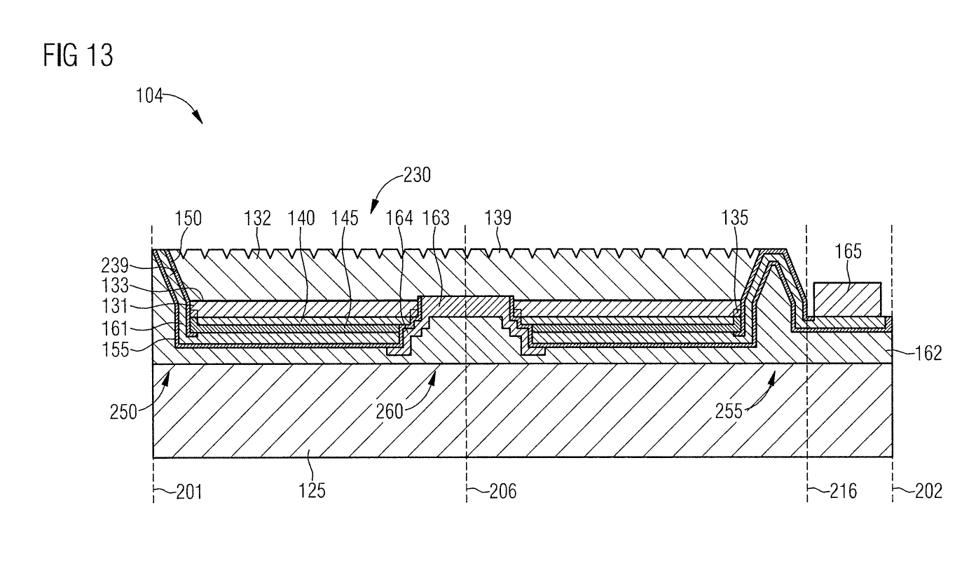

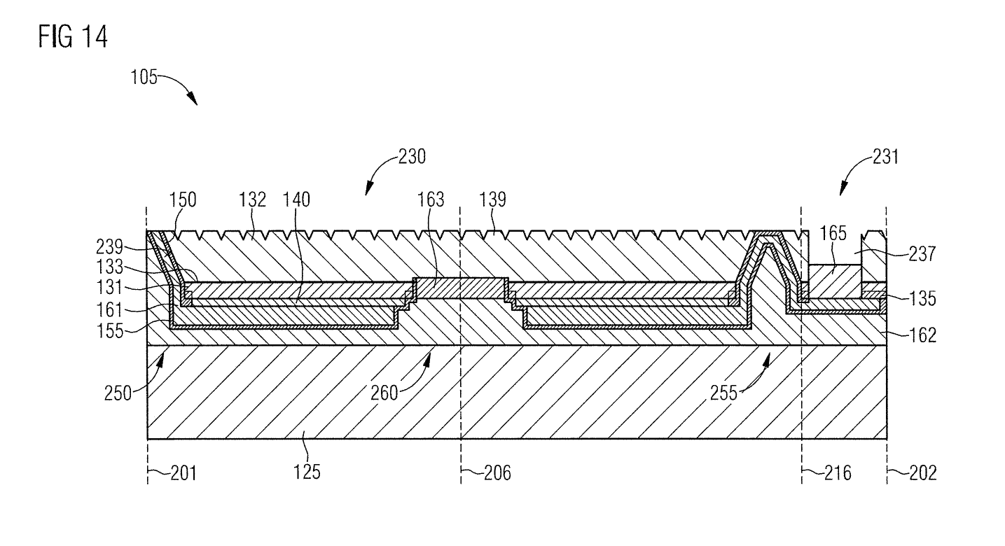

Complete removal of semiconductor material in the region of the contact pad 165 to be produced as illustrated in FIG. 12 is also present in the examples in FIGS. 13 and 15 to 18. Alternatively, the configuration with the (merely) opened semiconductor structure 231 as shown in FIG. 8 can be provided in FIGS. 13 and 15 to 18. Complete removal of semiconductor material in the region of the contact pad 165 can likewise come into consideration for the example shown in FIG. 14.

FIG. 13 shows a further optoelectronic semiconductor chip 104. Compared to the semiconductor chip 101, the semiconductor chip 104 comprises an additional mirror that reflects light radiation at each of the plated-through holes 260 (combination mirror). An increase in brightness is possible as a result. For this purpose, in step 304 (cf. FIG. 10) the contact layer 163 is formed and structured after deposition onto the second semiconductor region 132 and the insulation layer 155 such that the contact layer 163, in a departure from FIG. 5, in the region of each of the plated-through holes 260, does not only have a layer portion arranged directly on the second semiconductor region 132. The contact layer 163 additionally has a circumferential funnel- or cup-shaped portion 164 arranged at the edge of the perforation on the insulation layer 155 and, if appropriate, protruding laterally at the end of the perforation.

FIG. 14 shows a further optoelectronic semiconductor chip 105. In contrast to the semiconductor chip 101, no metallic layer 145 covering the mirror layer 140 is formed in the semiconductor chip 105. As a result, in a departure from FIG. 4, the first connection layer 161 produced in step 304 (cf. FIG. 10) adjoins the mirror layer 140, and is therefore electrically connected to the first semiconductor region 131 of the semiconductor body 230 only by the mirror layer 140. The omission of the metallic layer 145 enables simpler production.

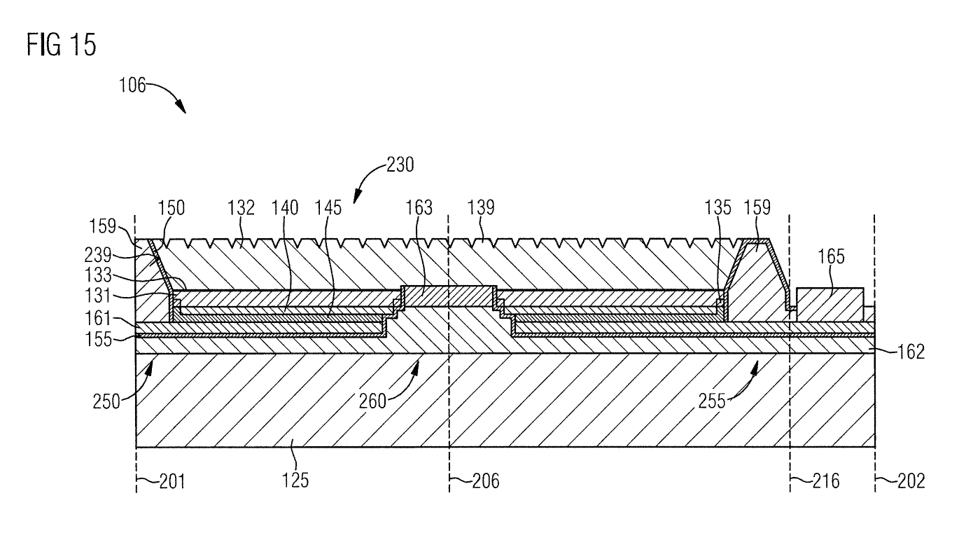

FIG. 15 shows a further optoelectronic semiconductor chip 106. The semiconductor chip 106 comprises a layer composed of an insulating material 159 in a region which extends circumferentially around the semiconductor body 230 and which is present laterally with respect to the passivation layer 150 arranged on the lateral surface 239. The insulating material 159 can, for example, be SiO₂.

The semiconductor chip 106 can be produced by a procedure in which the insulating material 159 is deposited after the process of forming the passivation layer 150 (step 303 in FIG. 10, cf. FIG. 3) on the substrate side with the semiconductor structures 230, 231, and a polishing or grinding process such as CMP (Chemical Mechanical Polishing), for example, to planarize the surface is subsequently carried out. Cavities in the form of the trench structure 250 and the trench region 255 thereof can be filled in this way. The further processes from among those described above of forming the connection structure (step 304 in FIG. 10) can subsequently be carried out. In this case, the connection layer 161 is also applied to the insulating material 159 and therefore has, like the other layers 155, 162 produced subsequently, a planar configuration in the region of the trench structure 250 now filled by the insulating material 159. This procedure affords the possibility of avoiding cavities or voids in relation to the bonding process (step 305 in FIG. 10). Before the process of forming the contact pad 165 carried out at the end of the production method, not only is semiconductor material removed in the region of the contact pad 165 to be produced, but also part of the insulating material 159 is removed in this region to form an opening extending to the connection layer 161.

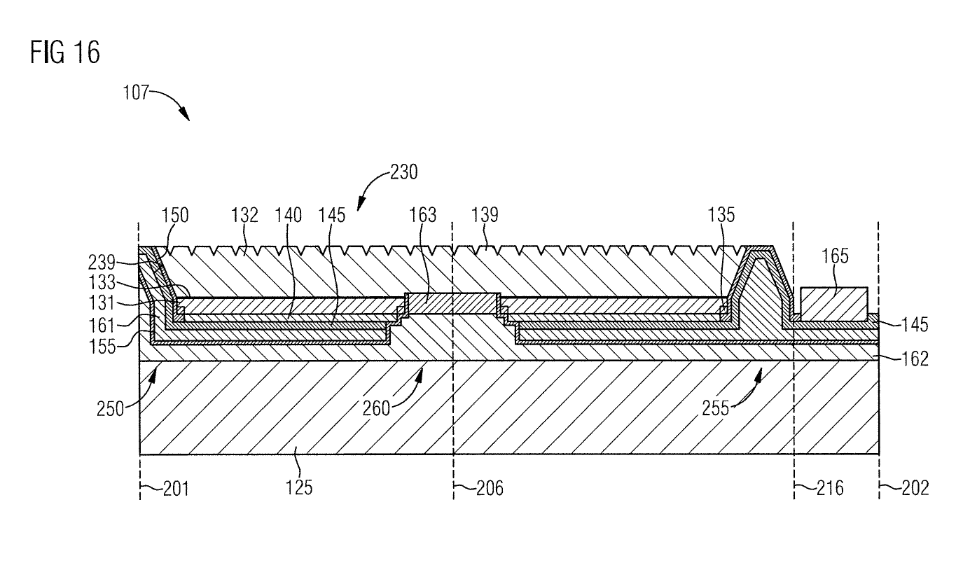

FIG. 16 shows a further optoelectronic semiconductor chip 107. In the semiconductor chip 107, compared to the semiconductor chip 101, the metallic layer 145 is provided not just in the region of the mirror layer 140. The layer 145 additionally also runs laterally with respect to the semiconductor body 230 on the passivation layer 250 as far as the front side of the semiconductor chip 107 and as far as that region in which the contact pad 165 is formed. In this configuration, therefore, the semiconductor body 230 is also laterally completely surrounded by a partial region of the metallic layer 145 arranged on the passivation layer 150. The contact pad 165 is arranged on the metallic layer 145.

The semiconductor chip 107 can be produced by a procedure in which the metallic layer 145 is applied after the process of forming the passivation layer 150 in the context of step 304 (cf. FIG. 10) on the substrate side with the semiconductor structures 230, 231 and is structured. During structuring, in particular, openings are formed in the region of the plated-through holes 260 to be produced. In a departure from FIG. 4, the first connection layer 161 produced subsequently can be arranged only on the metallic layer 145. In this case, the process of removing semiconductor material (step 306 in FIG. 10) carried out prior to the process of forming the contact pad 165 has the consequence that the metallic layer 145, rather than the connection layer 161 situated underneath, is exposed in this region. This is the case even if, in a departure from FIG. 16, the entire semiconductor material is not removed in this region, rather an opening (now extending to the layer 145) is instead formed in the semiconductor structure 231.

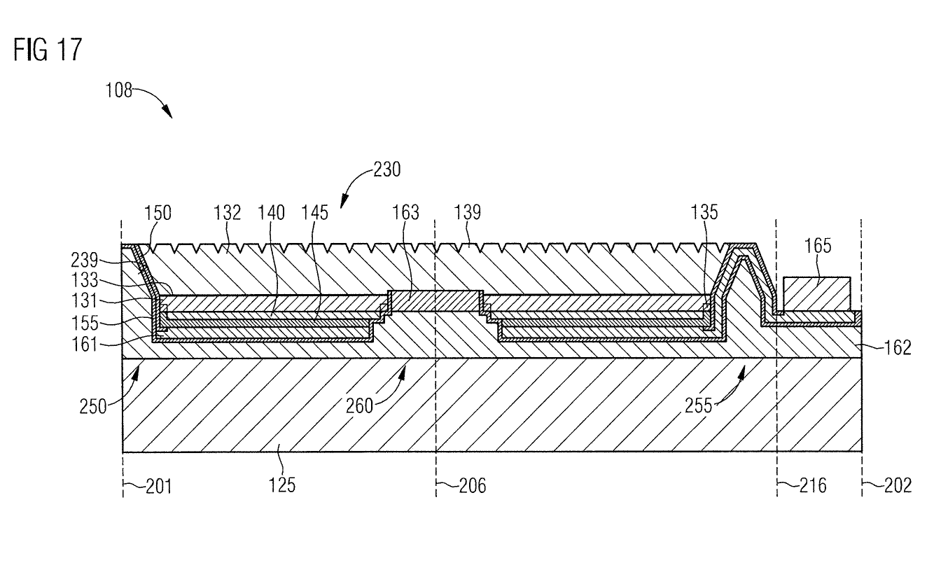

FIG. 17 shows a further optoelectronic semiconductor chip 108. In the semiconductor chip 108, compared to the semiconductor chip 101, the first connection layer 161 has no partial region completely surrounding the lateral surface 239 of the semiconductor body 230 or the passivation layer 150. This is associated with a saving of material. During production of the semiconductor chip 108, in step 304 (see FIG. 10), in a departure from FIG. 4, the connection layer 161 is no longer formed in the region of the entire trench structure 250 extending circumferentially around the semiconductor structure 230. A corresponding connecting region of the connection layer 161 is provided only in the trench region 255 between the two semiconductor structures 230, 231, by which connection region the partial regions of the connection layer 161 arranged on the semiconductor structures 230, 231 are connected. This has the consequence that in that region laterally with respect to the lateral surface 239 in which the connection layer 161 is omitted, the insulation layer 155 is also arranged on the passivation layer 150 and therefore directly adjoins the latter.

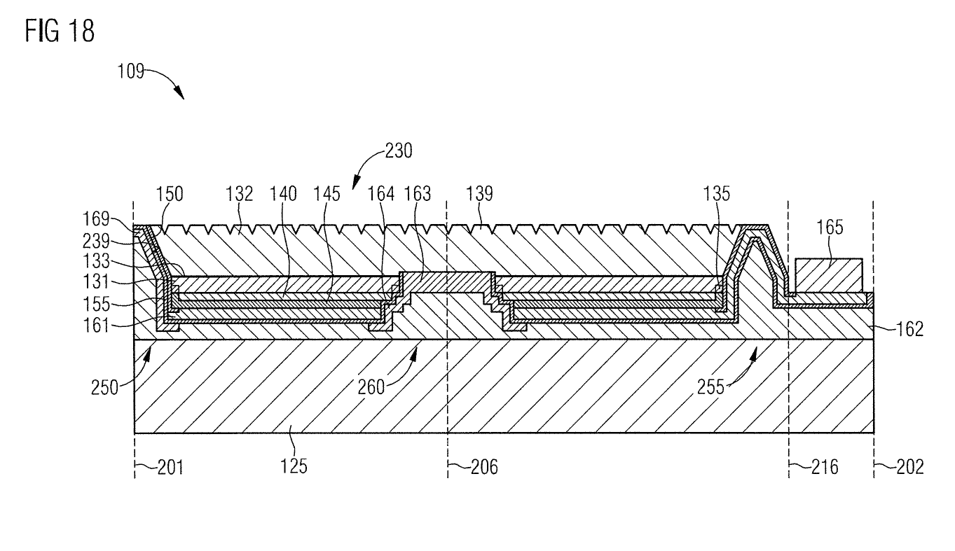

FIG. 18 shows a further optoelectronic semiconductor chip 109 comprising a combination mirror. In the semiconductor chip 109, comparably with the semiconductor chip 108, the first connection layer 161 has no partial region extending completely circumferentially around the semiconductor body 230 at the edge. This affords the possibility of arranging a mirror layer 169, provided to reflect light radiation, in the circumferential region, i.e., substantially in the entire region of the trench structure 250 apart from the trench region 255. An increase in brightness can be obtained as a result. As shown in FIG. 18, the mirror layer 169 is arranged on the insulation layer 155 and thus between the insulation layer 155 and the second connection layer 162. The mirror layer 169 can partly also project from the trench structure 250 as indicated in FIG. 18 on the basis of the partial region extending horizontally toward the right.

The semiconductor chip 109 furthermore has the configuration explained with reference to FIG. 13 with the layer portions 164 serving as mirrors in the region of the plated-through holes 260. The semiconductor chip 109 can be produced by a procedure in which, in step 304 (cf. FIG. 10), in a departure from FIG. 5, the deposited contact layer 163 is structured such that both the portions 164 in the region of the plated-through holes 260 and the mirror layer 169 extending laterally circumferentially around the semiconductor structure 230 are present.

In the above-described examples, provision is made for structuring the semiconductor layer sequence 130 formed on the starting substrate 120 such that semiconductor material is removed as far as the starting substrate 120. As a result, the semiconductor structure 230 produced can already have the shape of the semiconductor body 230 of the semiconductor chip used to emit light radiation. Alternatively, a two-stage mesa structuring of the semiconductor layer sequence 130 can be given consideration, wherein a first structuring step is carried out prior to transfer to the carrier substrate 125 or prior to forming the connection structure and a second structuring step is carried out after transfer. In this case, provision is made to carry out the first structuring step such that at least the first semiconductor region 131 and the active zone 133 are exposed at the lateral surface 239 of the semiconductor structure formed as a result. These regions are subsequently passivated. The two-stage procedure is a further possibility to minimize cavities in relation to connecting the connection structure to the carrier substrate 125. One possible method in this regard is explained in greater detail below with reference to the following figures.

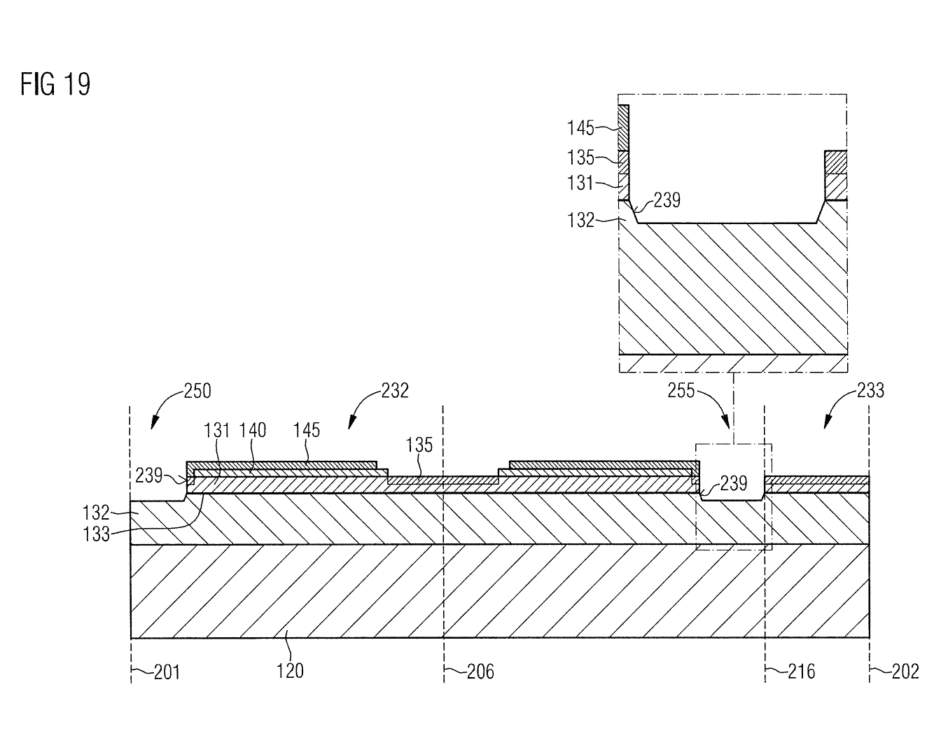

FIGS. 19 to 23 show, in a schematic lateral sectional view, production of a further optoelectronic semiconductor chip 110, which can likewise be a light-emitting diode chip. Apart from the difference presented above, production of the semiconductor chip 111 is carried out comparably with the above-described production of the semiconductor chip 101. Therefore, here, too, with regard to details concerning, for example, usable materials, implementable fabrication processes, possible advantages and the like, reference is made to the explanations above. The plan view illustration in FIG. 9 and the flow diagram in FIG. 10 can be applied in the same way.

FIG. 19 shows the starting substrate 120 after the process of forming the starting arrangement (step 301 in FIG. 10, cf. FIG. 1) and the process of structuring the semiconductor layer sequence 130 formed on the starting substrate 120 (step 302 in FIG. 10). The semiconductor layer sequence 130 is structured such that material of the semiconductor layer sequence 130 is removed beyond the active zone 133 into the second semiconductor region 132, but not as far as the starting substrate 120. As a result of the structuring, two semiconductor structures 232, 233 are formed (per semiconductor chip 110 to be produced), the semiconductor structures being present in the form of elevations. The structuring is carried out by an etching process, preferably a dry-chemical etching process in which material of the semiconductor layer sequence 130 is removed in an etching region surrounding the semiconductor structures 232, 233 to be produced.

Since the material removal does not take place as far as the starting substrate 120, the semiconductor structures 232, 233 are still connected to one another by the second semiconductor region 132. Furthermore, the starting substrate 120 is not exposed in the region of the trench structure 250 produced by the etching. The trench structure 250 here, too, is composed of continuous partial regions surrounding individual semiconductor structures 232, 233 in a frame-shaped fashion. The trench region 255 present between the two semiconductor structures 232, 233 shown in FIG. 19 is supplementarily illustrated in an enlarged view.

The semiconductor structures 232, 233 can likewise have the shape shown in FIG. 9 in plan view. In this case, too, the sectional illustration in FIGS. 19 to 23 relates to the sectional plane indicated with the aid of the sectional line A-A in FIG. 9.

The semiconductor structure 232, in the region of which a semiconductor body 240 of the semiconductor chip 110 is formed only in a later method stage, has, in the region of the side on which the arrangement comprising the two layers 140, 145 is present, the same lateral external dimensions as the layers 140, 145 or as the metallic layer 145 extending around the mirror layer 140. The semiconductor structure 232 has a circumferential lateral surface 239 at which the first semiconductor region 131, the active zone 133 and the second semiconductor region 132 are exposed. The circumferential lateral surface 239 comprises all mutually adjoining side faces or side flanks of the semiconductor structure 232.

As becomes clear in particular with reference to the enlarged illustration of the trench region 255, the side faces of the semiconductor structure 232 at least in the region of the second semiconductor region 132 can run at an oblique angle with respect to a plane predefined by the starting substrate 120 such that the semiconductor structure 232 has a shape at least partly widening in the direction of the starting substrate 120. It is also possible for the side faces to run obliquely with respect to the starting substrate 120 over the entire height of the semiconductor structure 232. This applies in the same way to the further semiconductor structure 233, only one side flank of which is shown at the auxiliary line 216.

Since the structuring of the semiconductor layer sequence 130 is carried out in a relatively early method stage, deposition of particles or layers at the lateral surface 239 of the semiconductor structure 232 produced by the structuring, and thus the risk of a shunt, can be avoided. This can be fostered further by the dry-chemical etch.

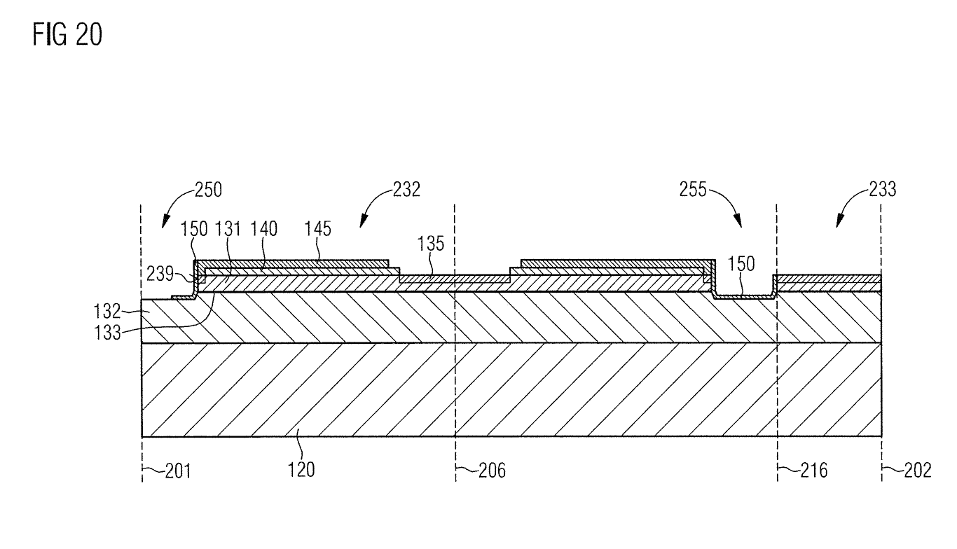

Afterward, as shown in FIG. 20, the insulating passivation layer 150 provided to passivate the circumferential lateral surface 239 of the semiconductor structure 232 is deposited on the substrate side with the semiconductor structures 232, 233 and subsequently structured (step 303 in FIG. 10). The passivation layer 150 is arranged on the entire circumferential lateral surface 239 of the semiconductor structure 232 such that the semiconductor regions 131, 132 previously exposed in this region and the active zone 133 are covered. In this way, the lateral surface 239 is protected in subsequent processes such that electrical shunts are prevented.

As shown in FIG. 20, the passivation layer 150 laterally completely enclosing the semiconductor structure 232 can be formed such that the passivation layer 150 extends as far as the arrangement comprising the two layers 140, 145 present on the top side of the semiconductor structure 232 and laterally surrounds the metallic layer 145 at the edge. The passivation layer 150 is furthermore also arranged in the region of the trench structure 250, as shown in FIG. 20 on the left-hand side. In this case, the passivation layer 150 has a partial region extending away from the lateral surface 239, is arranged on the second semiconductor region 132 and extends circumferentially around the semiconductor structure 232. The passivation layer 150 is present in the trench region 255, too, as is shown on the right-hand side in FIG. 20. In this case, the passivation layer 150 extends right onto the side face(s) of the semiconductor structure 233 opposite the lateral surface 239 of the semiconductor structure 232, and ends at this location substantially in the region of the top side of the semiconductor structure 233.

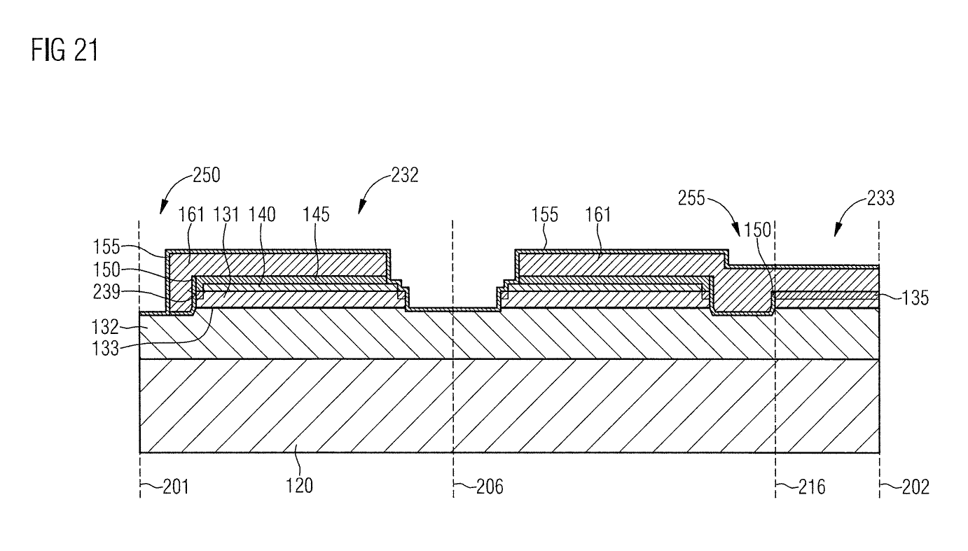

Afterward, in an analogous manner, the connection structure comprising the layers 155, 161, 162, 163 and the plated-through holes 260 is formed on the substrate side with the semiconductor structures 232, 233 (step 304 in FIG. 10). FIG. 21 shows a method stage after the process of forming the structured first connection layer 161, the process of producing cutouts in the semiconductor structure 232 in the region of the plated-through holes 260 to be produced, which extend as far as the second semiconductor region 132 and (initially) expose the second semiconductor region 132 at these locations, and the process of applying the insulation layer 155 on the layers 161, 145, 140 and semiconductor regions 131, 132 present at this side in this stage.

The first connection layer 161 is substantially arranged on the entire semiconductor structure 232 or on the layers 145, 150 present on the semiconductor structure 232 and formed with openings for the six plated-through holes 260 to be produced (cf. FIG. 9). The first connection layer 161 furthermore has a partial region in the region of the trench structure 250 arranged on the passivation layer 150 in this region and extends completely laterally circumferentially around the semiconductor structure 232 or the lateral surface 239 thereof. Furthermore, as shown on the right-hand side in FIG. 4, the first connection layer 161 has a partial region extending through the trench region 255 right onto the top side of the further semiconductor structure 233. This enables an electrical connection from a contact pad 165 produced in this region to the first semiconductor region 131 of a semiconductor body 240 of the semiconductor chip 110 which is produced later in the region of the semiconductor structure 232.

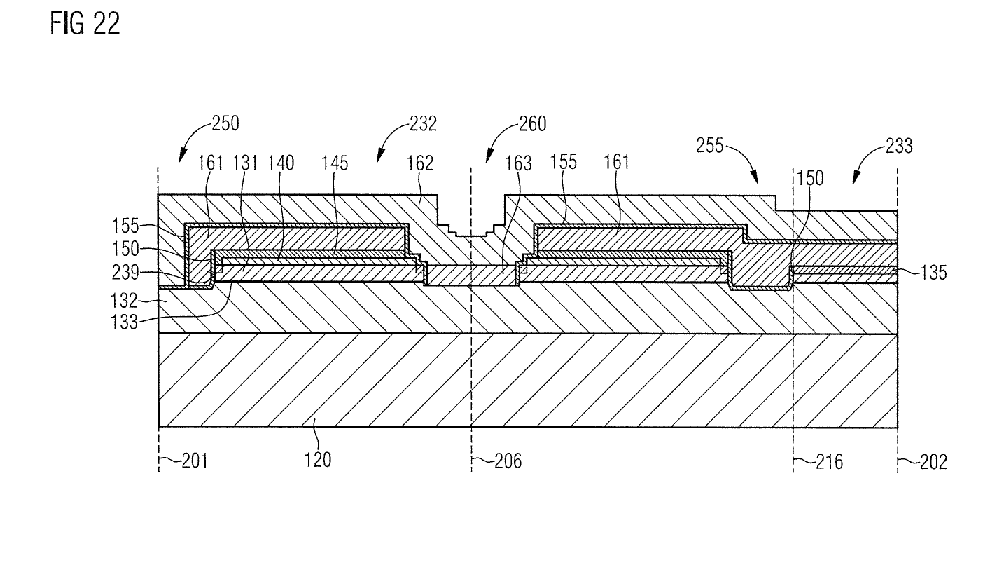

FIG. 22 shows a further method stage, in this case after the process of structuring the insulation layer 155 to expose the second semiconductor region 132 in the region of the plated-through holes 260 to be produced, the process of forming the portions of the contact layer 163 provided at these locations, and the process of forming the second connection layer 162 on the layers 155, 163 present at this side in this stage. The plated-through holes 260 are formed by applying the second connection layer 162, which is separated from the first connection layer 161 by the insulation layer 155.

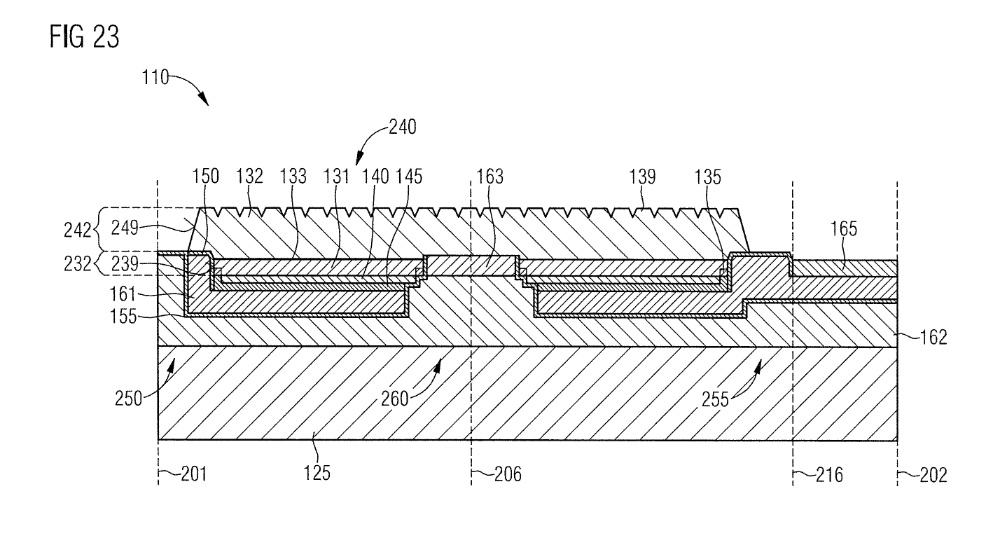

Afterward, the layer arrangement produced on the starting substrate 120 is transferred to the carrier substrate 125 or the connection structure connects thereto in a bonding process (step 305 in FIG. 10). Further processes (step 306 in FIG. 10) are subsequently carried out to complete the optoelectronic semiconductor chip 110 shown in FIG. 23. They include removing the starting substrate 120, and roughening for the purpose of forming a coupling-out structure 139 at that side of the second semiconductor region 132 which is exposed by removal of the starting substrate 120. The second semiconductor region 132 is (still) continuous in this stage.

After roughening, in the context of step 306, a further or second structuring of the semiconductor layer sequence 130 is carried out, as a result of which, as is shown in FIG. 23, a separate semiconductor body 240 is produced. The semiconductor body 240 serves as a mesa to emit light radiation in the semiconductor chip 110 and is formed in the region of the previously produced semiconductor structure 232. The second structuring step can be carried out by wet-chemical etching, for example. During structuring, semiconductor material is removed in a region surrounding the semiconductor body 240 to be produced as far as the passivation layer 150, the insulation layer 155 and the first connection layer 161. As shown in FIG. 23, it is also possible to remove the entire semiconductor material in the region of the semiconductor structure 233 previously present. In this region, furthermore, the contact pad 165 serving as a front-side contact is formed on the first connection layer 161 exposed by the structuring. The further processes mentioned above (thinning back the carrier substrate 125, forming a rear-side contact on the carrier substrate 125, singulation) can be carried out afterward.

The semiconductor body 240 comprises the semiconductor structure 232 produced in the first structuring step, and a mesa-shaped elevation 242 projecting at the front side of the semiconductor chip 110, the elevation being produced in the second structuring step. The semiconductor body 240 has a circumferential lateral surface 249 comprising the previously passivated lateral surface 239. The passivated lateral surface 239 thus constitutes part of the lateral surface 249 of the semiconductor body 240.

In this case, the elevation 242 is formed with larger external dimensions than the semiconductor structure 232. This has the effect that the semiconductor body 240, as shown in FIG. 23, has a stepped contour at the sides and, consequently, the lateral surface 249 has a stepped shape. Furthermore, the semiconductor body 240, only in the region of the semiconductor structure 232 produced in the first structuring step, is enclosed by the passivation layer 150 and the first connection layer 161 arranged laterally with respect to the passivation layer 150.

In the optoelectronic semiconductor chip 110, correspondingly, the first semiconductor region 131 of the semiconductor body 240 electrically connects to the contact pad 165, arranged laterally alongside the semiconductor body 240, by the mirror layer 140, the metallic layer 145 and the first connection layer 161. The second semiconductor region 132 of the semiconductor body 240 electrically connects to the rear-side contact (not shown), arranged on the carrier substrate 125, via the plated-through holes 260, the second connection layer 162 and the carrier substrate 125. In this way, an electric current flow through the semiconductor body 240 can be brought about, as a result of which the active zone 133 emits light radiation. The light radiation can be emitted substantially via the front or light exit side of the semiconductor body 240 with the coupling-out structure 139, and in part also via the side flanks of the elevation 242. A radiation proportion emitted by the active zone 133 in the direction of the carrier substrate 125 can be reflected in the direction of the front side by the mirror layer 140.

The examples explained with reference to the figures constitute preferred examples. Further examples which can comprise further modifications or combinations of features are possible alongside the examples described and depicted.

By way of example, other materials can be used instead of the materials specified above, and numerical indications above, for example, concerning layer thicknesses, numbers of plated-through holes 260 and the like, can be replaced by other indications. With regard to other materials, it is possible, for example, to use a carrier substrate 125 composed of a different (doped) semiconductor material, for example, silicon. A starting substrate 120 can also comprise a semiconductor material such as silicon, for example, and can be removed by etching, for example, after bonding onto a carrier substrate 125. Furthermore, it is possible for inverse conductivities with respect to the above-indicated conductivities of the semiconductor regions 131, 132 to be present instead of the above-indicated conductivities. Furthermore, optoelectronic semiconductor chips based on the above approaches can be formed with other shapes and geometries, and with further components, structures and/or layers. With regard to other geometries, it is possible, in particular, to depart from the shapes shown in FIG. 9.

Further combinations of examples can be employed alongside the combinations presented above. By way of example, it is possible to form the semiconductor chips 105, 106, 107 from FIGS. 14, 15, 16 with the additional mirror 164 (explained with reference to FIG. 13) in the region of the plated-through holes 260. Furthermore, for example, a planarization with the aid of the insulating material 159, as was explained with reference to FIG. 15, can be used in the production of the semiconductor chips 104, 105, 107 in FIGS. 13, 14, 16.

With regard also to the production method in FIGS. 19 to 23 with the two-stage structuring of the semiconductor layer sequence 130 to form the semiconductor body 240, it is possible to use configurations from the previous figures. By way of example, additional mirrors 164 can be formed in the region of the plated-through holes 260. Consideration can also be given not to removing the entire semiconductor material in the region of the semiconductor structure 233, but rather to producing instead an opening that exposes the connection layer 161 in this part of the semiconductor layer sequence. Afterward, a contact pad 165 can be produced here, too, such that a structure similar to FIG. 8 can be present. Furthermore, provision can be made to form an additional passivation layer 157 at the front side of the semiconductor chip 110, the additional passivation layer covering at least the semiconductor body 240 or the elevation 242.

Modifications are likewise possible with regard to the structure of the passivation layer 150. With reference to FIG. 20, it is conceivable, for example, to form the passivation layer 150 with a configuration corresponding to FIG. 3, according to which the passivation layer 150 extends around the metallic layer 145 arranged on the semiconductor structure 232 at the outer edge. Furthermore, the passivation layer 150 can also be led onto the top side of the semiconductor structure 233 and therefore extend around the latter at the edge. In an analogous manner, it is possible for a configuration corresponding to FIG. 20 to be present in production of the semiconductor chip 101 from FIG. 8 (and the chips from FIGS. 11 to 18). In this case, the passivation layer 150 can extend only as far as the layer 145 and not around the latter, and the passivation layer 150 can not be arranged on the top side of the semiconductor structure 231.

Although aspects of our LEDs and methods have been more specifically illustrated and described in detail by preferred examples, nevertheless the aspects of our LEDs and methods are not restricted by the examples disclosed, and other variations can be derived therefrom by those skilled in the art without departing from the scope of protection of the appended claims.

This application claims the priority of DE 102013105870.1, the disclosure of which is hereby incorporated by reference.

1-16. (canceled)

17. A method of producing an optoelectronic semiconductor chip comprising:
forming a semiconductor layer sequence on a starting substrate comprising a first and a second semiconductor region and, arranged there between, an active zone that generates radiation;
structuring the semiconductor layer sequence, wherein a semiconductor structure in the form of an elevation having a circumferential lateral surface is formed by material of the semiconductor layer sequence being removed in a region surrounding the semiconductor structure at least as far as a depth such that the active zone is exposed at the circumferential lateral surface;
forming a passivation layer arranged on the circumferential lateral surface of the semiconductor structure;
forming a connection structure in the region of the semiconductor structure after forming the passivation layer, comprising a first and a second conductive connection layer separated from one another, wherein the first connection layer electrically connects to the first semiconductor region, and the second connection layer via at least one plated-through hole electrically connects to the second semiconductor region;
forming a mirror layer in the region of the plated-through hole and/or in a region laterally surrounding the semiconductor structure;
connecting the connection structure to a carrier substrate; and
removing the starting substrate.

18. The method according to claim 17, wherein an insulation layer is formed which separates the second connection layer from the first connection layer.

19. The method according to claim 18, wherein the mirror layer is arranged between the insulation layer and the second connection layer.

20. The method according to claim 17, wherein material of the semiconductor layer sequence is removed as far as the starting substrate during the structuring of the semiconductor layer sequence.

21. The method according to claim 17, wherein structuring the semiconductor layer sequence comprises carrying out a dry-chemical etching process.

22. The method according to claim 17, wherein the passivation layer comprises silicon nitride.

23. The method according to claim 17, wherein, during the process of structuring the semiconductor layer sequence, a further semiconductor structure in the form of an elevation is formed laterally alongside the semiconductor structure, wherein the passivation layer is formed in the region of a trench between the semiconductor structure and the further semiconductor structure, and wherein the connection structure is formed in the region of the further semiconductor structure.

24. The method according to claim 17, wherein the first connection layer is formed such that the first connection layer comprises a partial region that laterally surrounds the semiconductor structure and is arranged on the passivation layer.

25. The method according to claim 17, wherein, before the process of structuring the semiconductor layer sequence, a conductive mirror layer is formed on the semiconductor layer sequence, and wherein the first connection layer electrically connects to the first semiconductor region by the conductive mirror layer.

26. The method according to claim 17, wherein the plated-through hole is formed by a perforation extending through the first connection layer, the first semiconductor region and the active zone into the second semiconductor region and which is insulated at the edge, wherein a contact layer contacting the second semiconductor region and a partial region of the second connection layer, said partial region contacting the contact layer, are arranged within the perforation.

27. The method according to claim 17, wherein, after the process of forming the passivation layer, a region laterally surrounding the semiconductor structure is filled with an insulating material.

28. The method according to claim 17, wherein, after the process of removing the starting substrate, a further passivation layer is formed and arranged on a front side of the optoelectronic semiconductor chip.

29. The method according to claim 17, wherein, during the process of structuring the semiconductor layer sequence, material of the semiconductor layer sequence is not removed as far as the starting substrate, and wherein, after the process of removing the starting substrate, further structuring of the semiconductor layer sequence is carried out to form a semiconductor body of the optoelectronic semiconductor chip, said semiconductor body comprising the semiconductor structure.

30. An optoelectronic semiconductor chip, comprising:
a carrier substrate;
a semiconductor body having a circumferential lateral surface, comprising a first and a second semiconductor region and, arranged there between, an active zone that generates radiation; and
a connection structure comprising a first and a second conductive connection layer, separated from one another, wherein the first connection layer electrically connects to the first semiconductor region and the second connection layer via at least one plated-through hole electrically connects to the second semiconductor region,
wherein the semiconductor body is surrounded by a passivation layer arranged on the lateral surface, and at least one further layer is arranged in a region surrounding the passivation layer.

31. The optoelectronic semiconductor chip according to claim 30, wherein the passivation layer extends as far as the top side of the second semiconductor region facing away from the carrier substrate.

32. The optoelectronic semiconductor chip according to claim 30, wherein the semiconductor body has a shape at least partly widening in the direction of a front side, via which light radiation is emittable.

33. The optoelectronic semiconductor chip according to claim 30, wherein the at least one further layer is one of the following layers:
the first connection layer;
a layer composed of an insulating material;
a conductive layer;
a conductive mirror layer;
an insulation layer by which the first and second connection layers are separated from one another; or
the second connection layer.

34. The optoelectronic semiconductor chip according to claim 30, wherein a mirror layer is arranged in the region of the plated-through hole and/or in a region laterally surrounding the semiconductor structure.

35. The optoelectronic semiconductor chip according to claim 34, wherein an insulation layer separates the second connection layer from the first connection layer, and a mirror layer is arranged between the insulation layer and the second connection layer.

36. A method of producing an optoelectronic semiconductor chip comprising:
forming a semiconductor layer sequence on a starting substrate, comprising a first and a second semiconductor region and, arranged there between, an active zone that generates radiation;
structuring the semiconductor layer sequence, wherein a semiconductor structure in the form of an elevation having a circumferential lateral surface is formed by material of the semiconductor layer sequence being removed in a region surrounding the semiconductor structure at least as far as a depth such that the active zone is exposed at the circumferential lateral surface;
forming a passivation layer arranged on the circumferential lateral surface of the semiconductor structure;
forming a connection structure in the region of the semiconductor structure after forming the passivation layer, comprising a first and a second conductive connection layer separated from one another, wherein the first connection layer electrically connects to the first semiconductor region and the second connection layer via at least one plated-through hole electrically connects to the second semiconductor region;
connecting the connection structure to a carrier substrate; and
removing the starting substrate.
